(19) United States
(12) Patent Application Publication
(10) Pub. No.: US 2024/0365534 A1
(43) Pub. Date: Oct. 31, 2024

(54) MEMORY DEVICE, METHOD OF MANUFACTURING MEMORY DEVICE, AND ELECTRONIC APPARATUS INCLUDING MEMORY DEVICE

(71) Applicant: INSTITUTE OF MICROELECTRONICS, CHINESE ACADEMY OF SCIENCES, Beijing (CN)

(72) Inventors: Huilong ZHU, Poughkeepsie, NY (US); Tianchun YE, Beijing (CN); Jun LUO, Beijing (CN)

(21) Appl. No.: 18/630,435

(22) Filed: Apr. 9, 2024

(30) Foreign Application Priority Data
Apr. 27, 2023 (CN) 202310470674.7

(51) Int. Cl. H10B 12/00; H10B 61/00; H10N 50/10

(52) U.S. Cl. CPC H10B 12/482; H10B 12/05; H10B 12/485; H10B 12/488; H10B 61/22; H10N 50/10

(57) ABSTRACT

A memory device, including: device layers vertically stacked on a substrate, each device layer including an array of active regions of selection transistors, the array including rows in a first direction and columns in a second direction, the active region including a lower source/drain region, a channel portion, and an upper source/drain region; bit lines arranged in the second direction and extending in the first direction along rows; word line layers vertically stacked and corresponding to the device layers, and each including word lines arranged in the first direction and extending in the second direction to at least partially surround a channel portion in a column of a device layer; sub bit lines extending vertically from each bit line and each electrically connected to a lower source/drain region in a row in each device layer above the bit line; and a memory element electrically connected to the upper source/drain region.

This application claims priority to Chinese Patent Application No. 202310470674.7, filed on Apr. 27, 2023 and entitled “MEMORY DEVICE, METHOD OF MANUFACTURING MEMORY DEVICE, AND ELECTRONIC APPARATUS INCLUDING MEMORY DEVICE”, the entire content of which is incorporated herein in its entirety by reference.

### TECHNICAL FIELD

The present disclosure relates to a field of semiconductors, and more particularly, to a memory device, a method of manufacturing the memory device, and an electronic apparatus including the memory device.

### BACKGROUND

In a horizontal device such as a Metal Oxide Semiconductor Field Effect Transistor (MOSFET), a source, a gate and a drain are arranged in a direction substantially parallel to a surface of a substrate. Due to such an arrangement, the horizontal device is difficult to be further scaled down. In contrast, in a vertical device, a source, a gate and a drain are arranged in a direction substantially perpendicular to the surface of the substrate. As a result, the vertical device is easier to be scaled down compared to the horizontal device.

### SUMMARY

The present disclosure provides a memory device, a method of manufacturing the memory device, and an electronic apparatus including the memory device.

According to an aspect of the present disclosure, there is provided a memory device, including: a plurality of device layers stacked on a substrate in a vertical direction relative to the substrate, wherein each of the plurality of device layers includes an array of active regions of selection transistors, the active regions in the array are arranged in rows in a first direction and in columns in a second direction, and the active region includes a lower source/drain region and an upper source/drain region at different heights relative to the substrate, as well as a channel portion located between the lower source/drain region and the upper source/drain region; a plurality of bit lines arranged in the second direction, wherein each of the plurality of bit lines extends in the first direction along a corresponding row in the array; a plurality of word line layers stacked in the vertical direction and corresponding to the plurality of device layers, respectively, wherein each of the plurality of word line layers includes a plurality of word lines arranged in the first direction, and each of the plurality of word lines extends in the second direction to at least partially surround a channel portion of an active region in a corresponding column of the device layer corresponding to the word line layer; a plurality of sub bit lines extending vertically from each of the plurality of bit lines, wherein each of the plurality of sub bit lines is electrically connected to a lower source/drain region of an active region in a corresponding row of the bit line in each device layer above the bit line; and a memory element electrically connected to the upper source/drain region of each active region.

According to another aspect of the present disclosure, there is provided a method of manufacturing a memory device, including: providing a plurality of device layers on a substrate, wherein each of the plurality of device layers includes a first source/drain layer, a channel defining layer, and a second source/drain layer sequentially stacked in a vertical direction relative to the substrate, and an isolation defining layer is provided between device layers; forming, in the plurality of device layers, a plurality of first processing channels extending vertically, wherein the plurality of first processing channels are arranged in a first direction and extend in a second direction intersecting with the first direction, and a bottom portion of each of the plurality of first processing channels is defined by a first source/drain layer in a lowermost device layer among the plurality of device layers; recessing in the first direction, via the first processing channel, an end portion of the channel defining layer in each device layer in the first direction relative to a corresponding end portion of the first source/drain layer and a corresponding end portion of the second source/drain layer, and forming a first gate position retaining layer in a resulting recess; replacing, via the first processing channel, a part of the isolation defining layer facing the first processing channel with an isolation layer; recessing in the first direction, via the first processing channel, the second source/drain layer in each device layer exposed in the first processing channel relative to the first source/drain layer in the device layer exposed in the first processing channel; forming, on the first source/drain layer in the lowermost device layer exposed at the bottom portion of the first processing channel, a sub bit line along a sidewall of the first processing channel, wherein the sub bit line is in contact with the first source/drain layer in each device layer exposed in the first processing channel; forming, in the plurality of device layers, a plurality of second processing channels extending vertically, wherein the plurality of second processing channels are arranged alternately with the first processing channels in the first direction and extend in the second direction, and the plurality of device layers form a step structure at the second processing channel; recessing in the first direction, via the second processing channel, the end portion of the channel defining layer in each device layer in the first direction relative to the corresponding end portion of the first source/drain layer and the corresponding end portion of the second source/drain layer, and forming a second gate position retaining layer in a resulting recess; replacing, via the second processing channel, a remaining part of the isolation defining layer facing the second processing channel with an isolation layer; forming a plurality of third processing channels that pass through the plurality of device layers, wherein the plurality of third processing channels are arranged in the second direction and extend in the first direction; growing, by selective epitaxial growth, a channel layer on a sidewall of each device layer exposed in the third processing channel; forming a plurality of fourth processing channels that pass through the plurality of device layers, wherein the plurality of fourth processing channels are arranged alternately with the third processing channels in the second direction and extend in the first direction; removing, via the fourth processing channel, the channel defining layer, the first gate position retaining layer, and the second gate position retaining layer; and forming, on the substrate, a word line layer corresponding to each device layer, wherein each word line layer includes a plurality of word lines, the word line extends in the second direction to at least partially surround a part of the channel layer between the first source/drain layer and the second source/drain layer.

According to another aspect of the present disclosure, there is provided an electronic apparatus including the memory device described above.

### BRIEF DESCRIPTION OF THE DRAWINGS

The above and other objects, features, and advantages of the present disclosure will be more clearly described through the following description of embodiments of the present disclosure with reference to the accompanying drawings, in which:

FIG. 1(a) schematically shows a partial perspective view of an array of selection transistors in a memory device according to an embodiment of the present disclosure, FIG. 1(b) schematically shows a partial perspective view of bit lines and active regions of an array of selection transistors in a memory device after removing word lines according to an embodiment;

FIGS. 2 to 46(b) show schematic diagrams of some stages in a process of manufacturing a memory device according to an embodiment of the present disclosure;

FIG. 47 schematically shows an equivalent circuit diagram of a memory device according to an embodiment of the present disclosure;

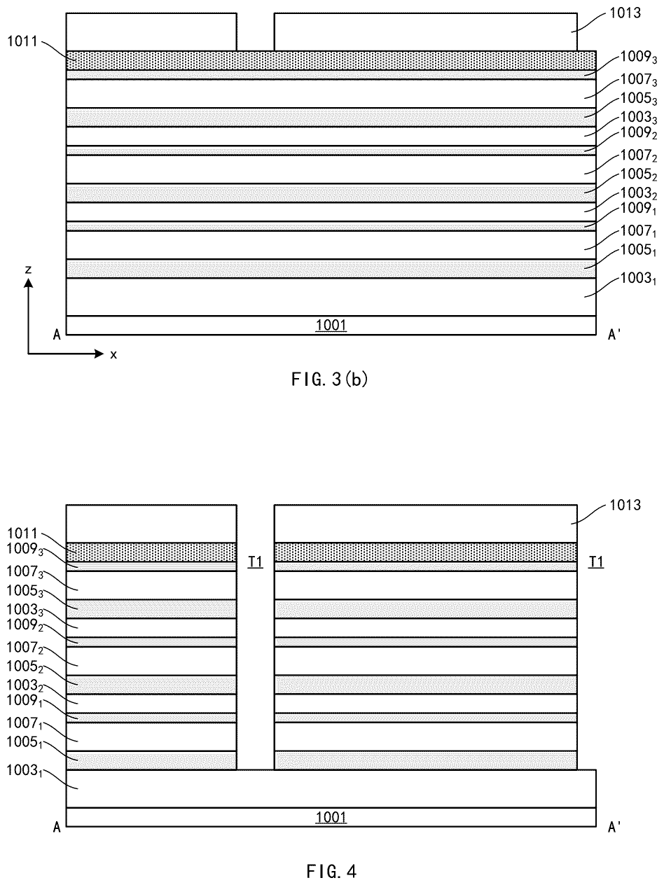

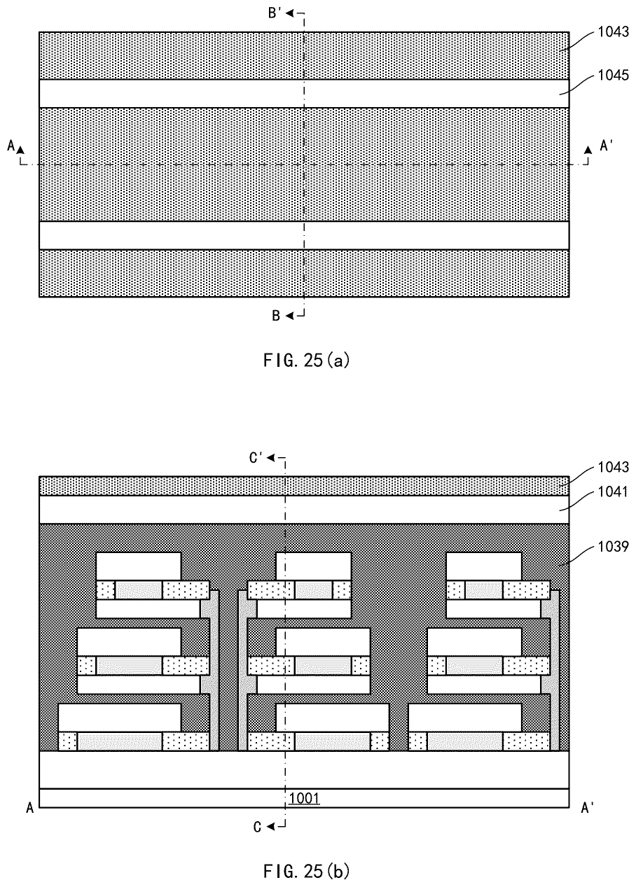

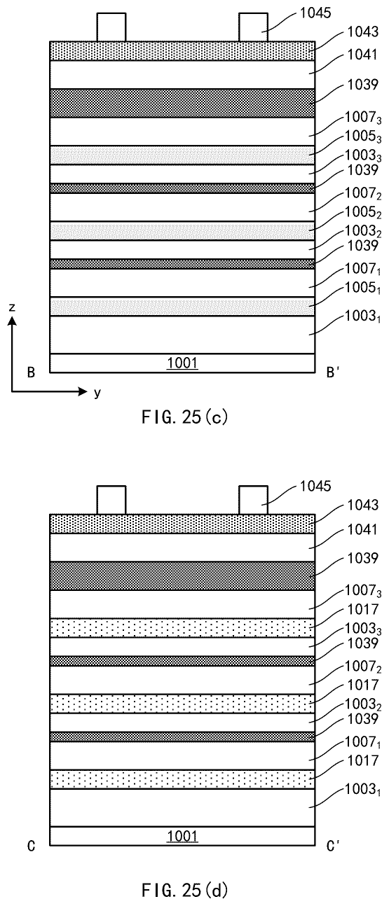

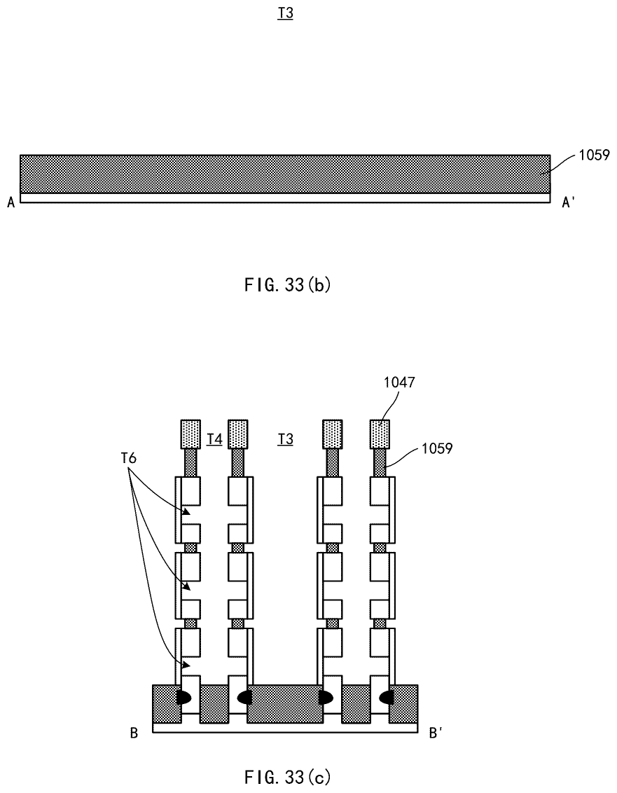

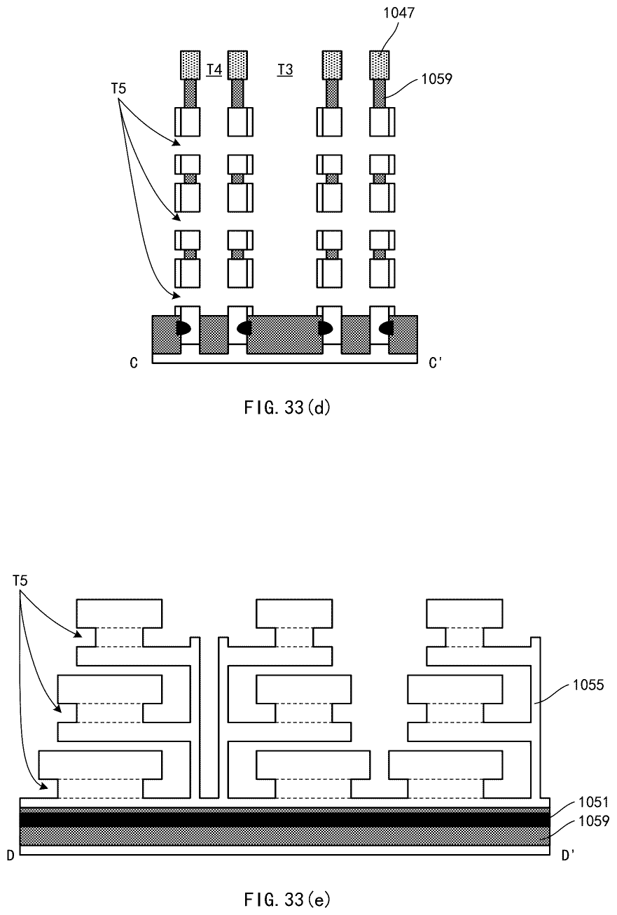

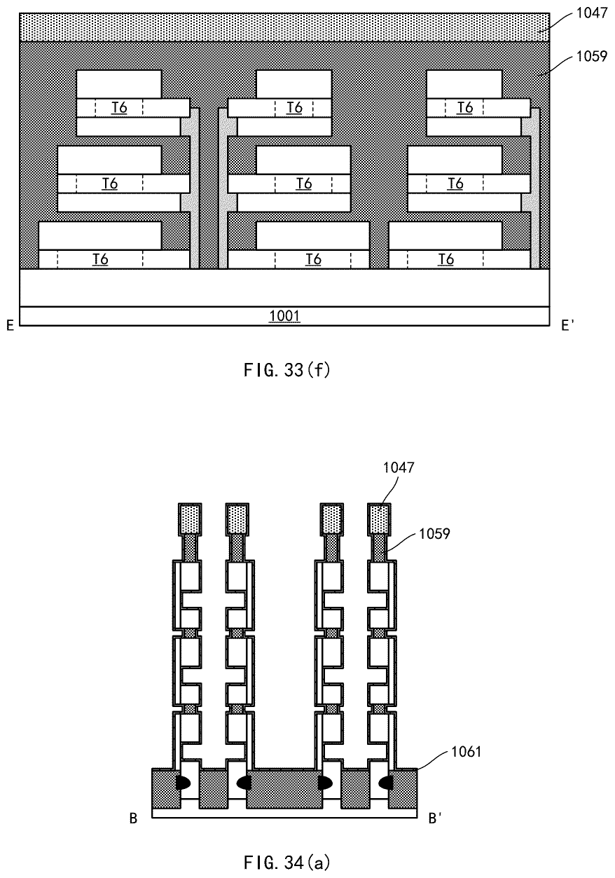

wherein FIGS. 3(a), 25(a), 33(a), 41(a) and 45(a) are top views, and FIG. 3(a) shows a position of line AA′, FIG. 25(a) shows a position of line BB′, and FIG. 33(a) shows positions of line DD′ and line EE′,

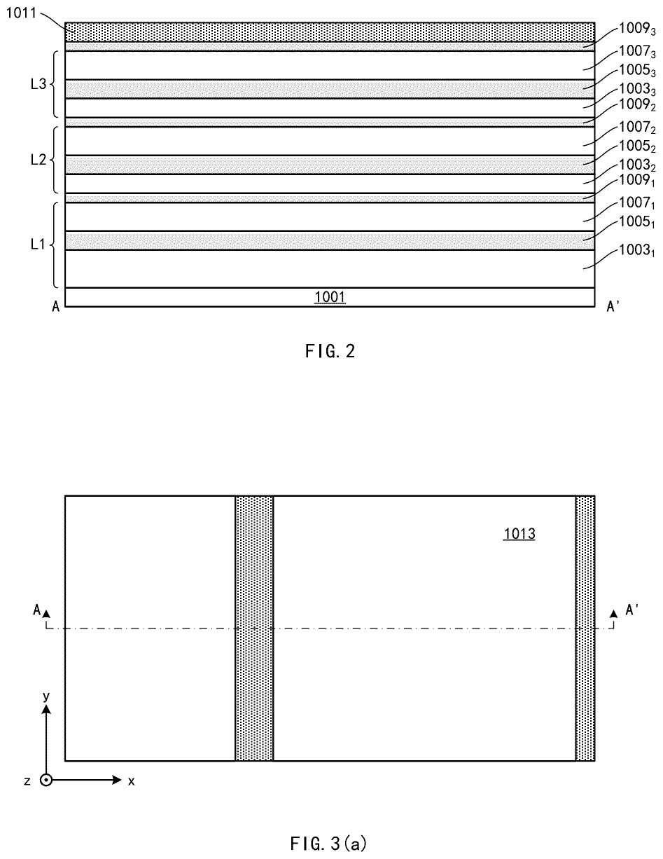

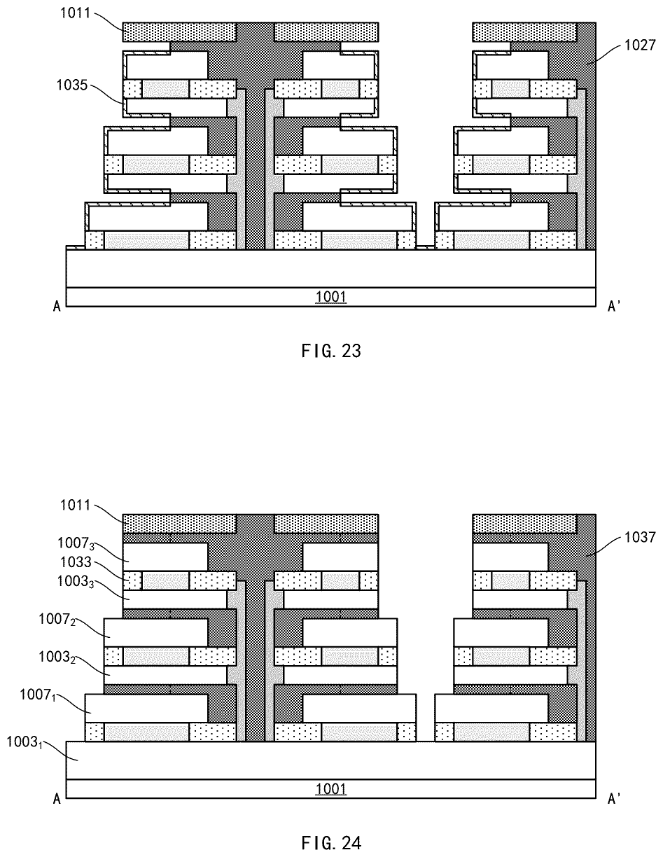

FIGS. 2, 3(b), 4 to 24, 25(b), 33(b), 40(a), 41(b), 42(a) and 44(a) are cross-sectional views taken along line AA′, and FIG. 25(b) shows a position of line CC′,

FIGS. 25(c), 26, 27, 28(a), 29, 30(a), 31(a), 32(a), 33(c), 34(a), 35(a), 36(a), 37(a), 38(a), 39(a) and 40(b) are cross-sectional views taken along line BB′,

FIGS. 25(d), 28(b), 30(b), 31(b), 32(b), 33(d), 34(b), 35(b), 36(b), 37(b), 39(b) and 40(c) are cross-sectional views taken along line CC′,

FIGS. 33(e), 34(c), 35(c), 41(c) and 42(b) are cross-sectional views taken along line DD′,

FIGS. 33(f), 34(d), 35(d), 41(d), 43, 44(b), 45(b), 46(a) and 46(b) are cross-sectional views taken along line EE′,

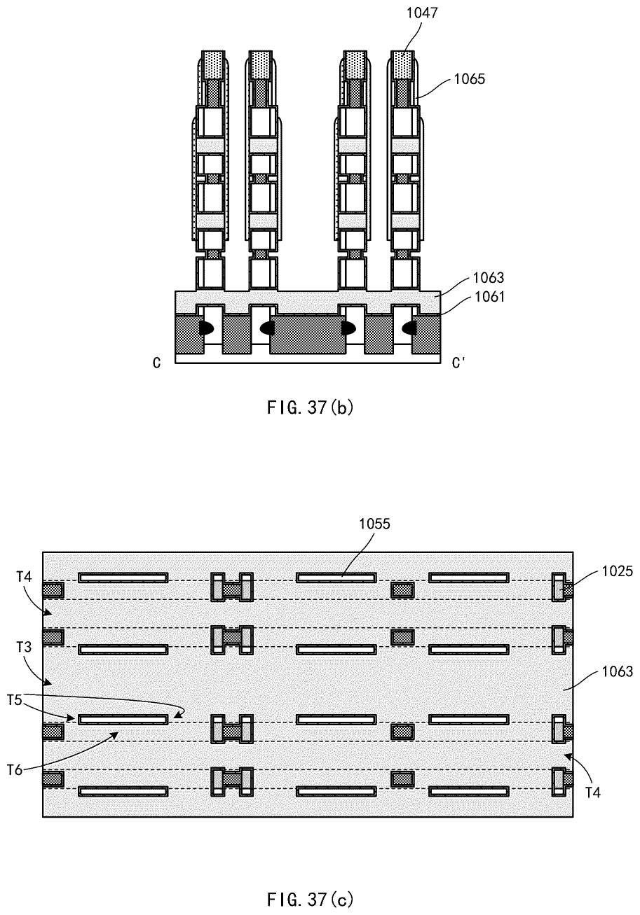

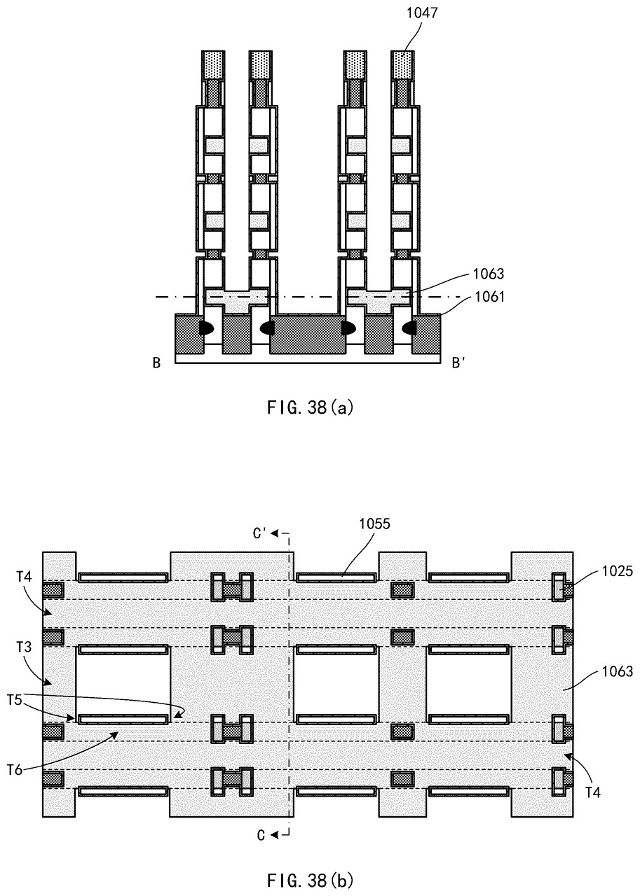

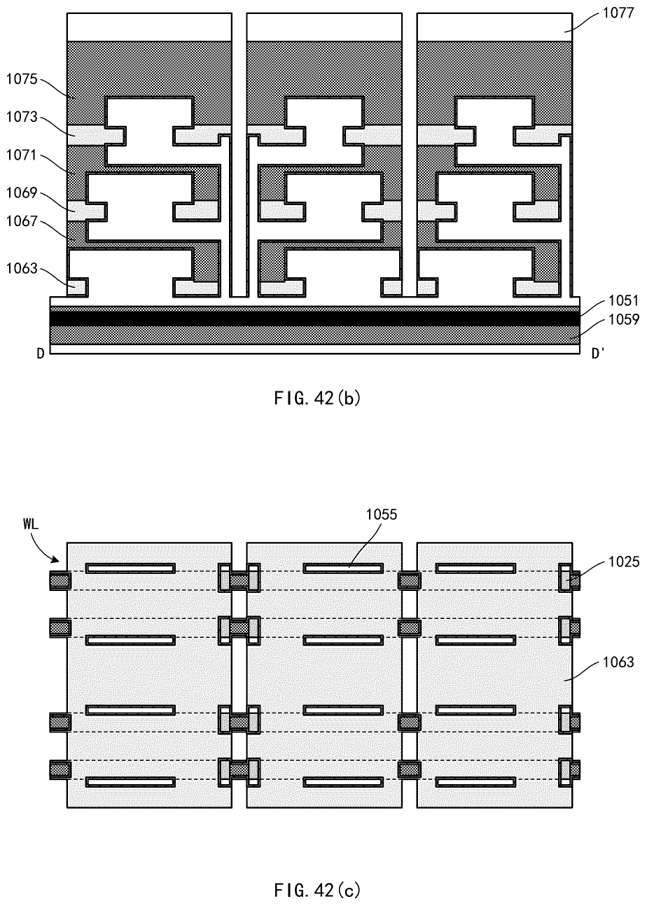

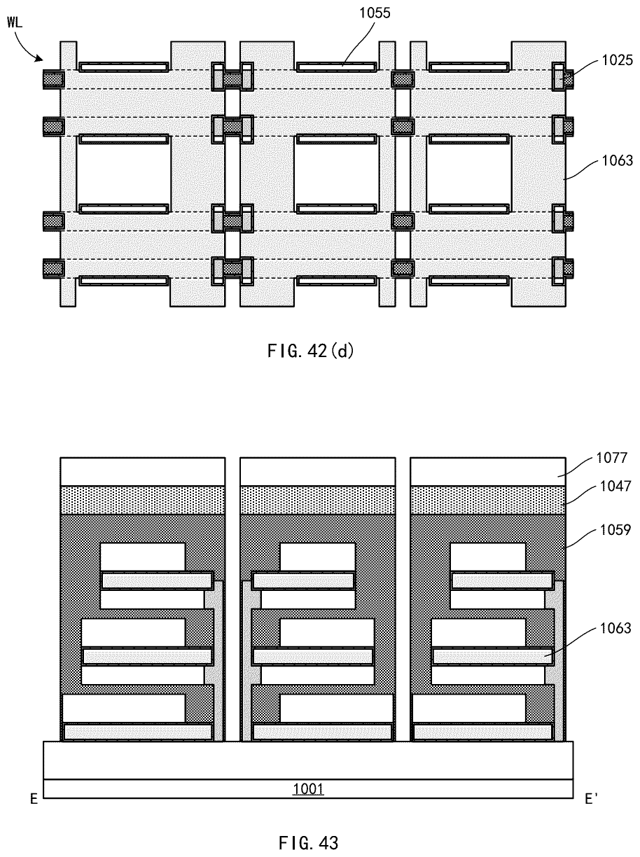

FIG. 37(c) is a cross-sectional view along a dotted line in FIG. 37(a), FIG. 38(b) is a cross-sectional view along a dotted line in FIG. 38(a), FIG. 42(c) is a cross-sectional view corresponding to FIG. 37(c), and FIG. 42(d) is a cross-sectional view corresponding to FIG. 38(b).

Throughout the drawings, the same or similar reference numbers indicate the same or similar elements.

### DETAILED DESCRIPTION OF EMBODIMENTS

Hereinafter, embodiments of the present disclosure will be described with reference to the accompanying drawings. However, it should to be understood that these descriptions are illustrative and not intended to limit the scope of the present disclosure. Further, in the following, known structures and technologies are omitted to avoid obscuring the concept of the present disclosure unnecessarily.

In the drawings, various structures according to embodiments of the present disclosure are schematically shown. However, they are not drawn to scale, and some features may be enlarged while some features may be omitted for sake of clarity. Moreover, shapes and relative sizes and positions of regions and layers shown in the drawings are also illustrative, and deviations may occur due to manufacture tolerances and technique limitations in practice. Those skilled in the art may also devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is reversed.

According to embodiments of the present disclosure, there is provided a novel three-dimensional (3D) memory device architecture. In this 3D architecture, selection transistors in memory cells are vertically stacked, which may provide a greater design space, reduce an occupied area, and enhance a device performance. The vertical stacked transistors may be connected to corresponding bit lines by using sub-bit lines. In the manufacturing process according to embodiments of the present disclosure, various self-alignment processes may be used to reduce an area, a space and a cost, as well as increase a yield.

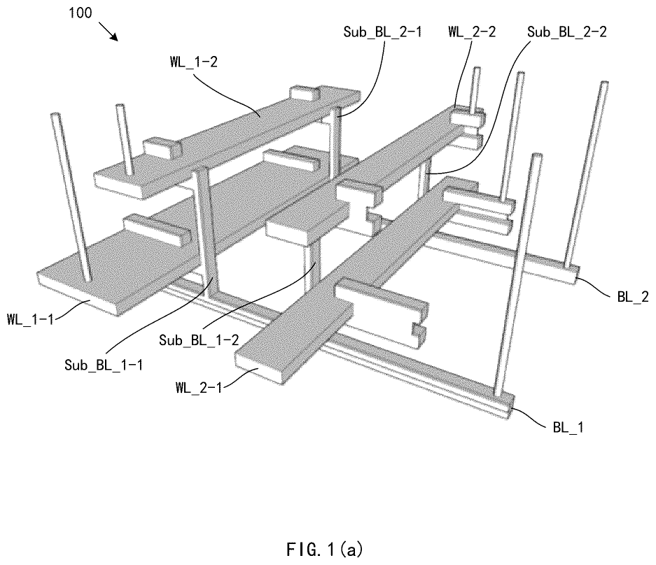

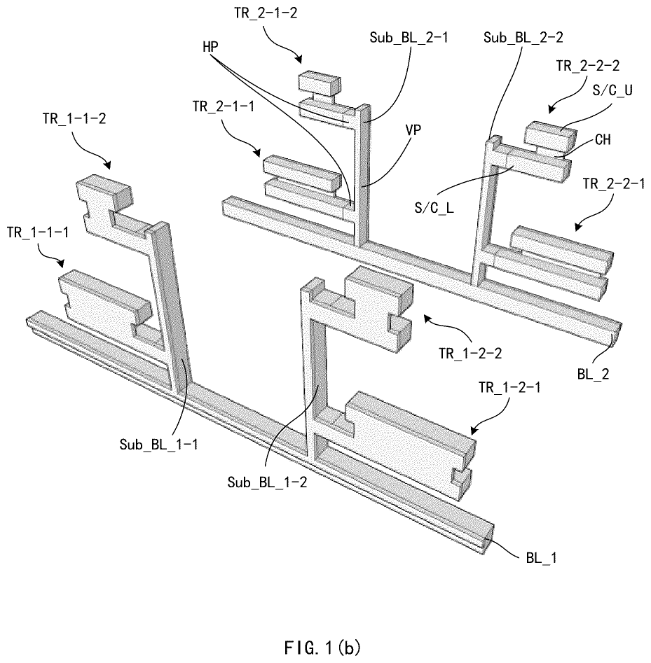

FIG. 1(a) schematically shows a partial perspective view of an array of selection transistors in a memory device according to an embodiment of the present disclosure, FIG. 1(b) schematically shows a partial perspective view of bit lines and active regions of an array of selection transistors in a memory device after removing word lines according to an embodiment.

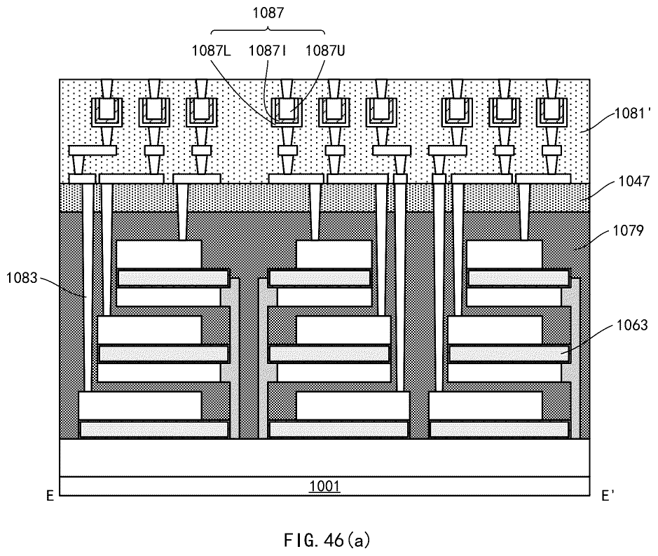

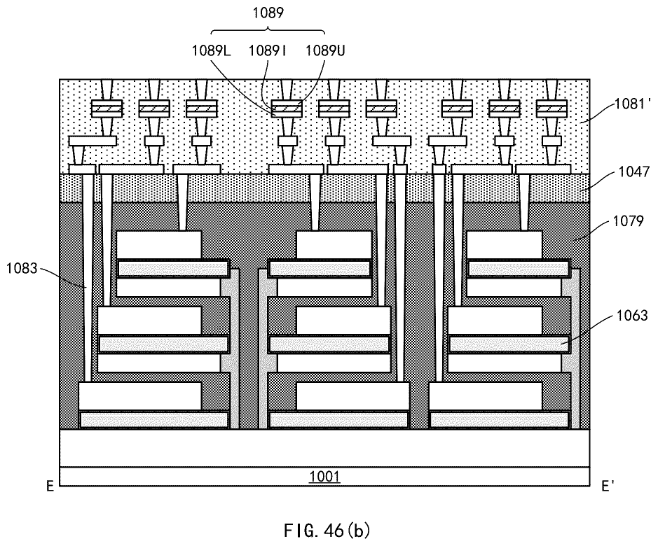

As shown in FIGS. 1(a) and 1(b), the memory device according to embodiments may include a three-dimensional (3D) array 100 of selection transistors and memory elements (for example, capacitors 1087 in FIG. 46(a), or magnetic tunnel junctions 1089 in FIG. 46(b)) electrically connected to the selection transistors. Such memory device may include a dynamic random access memory (DRAM) or a magnetic random access memory (MRAM). Each selection transistor and the memory element electrically connected to the selection transistor may form a memory cell (MC).

The figure schematically shows some selection transistors in the 3D array 100, such as selection transistors TR_1-1-1, TR_1-2-1, TR_2-1-1 and TR_2-2-1 located in the lower layer, as well as selection transistors TR_1-1-2, TR_1-2-2, TR_2-1-2 and TR_2-2-2 located in the upper layer. Although only two layers in the 3D array 100 are shown here, the present disclosure is not limited to this, but may include more layers, such as L layers (where L is a natural number greater than or equal to 2). In addition, the figure shows that each layer includes a 2×2 array of selection transistors, which is only for the convenience of illustration. In fact, each layer may include, for example, a M (rows)×N (columns) (where M and N are natural numbers greater than or equal to 2) array of selection transistors. Therefore, the 3D array 100 may include M×N×L selection transistors. Each selection transistor may be represented as TR_i-j-k (1≤i≤M, i may be called a row index; 1≤j≤N, j may be called a column index; 1≤k≤L, k may be called a layer index).

The selection transistors in the 3D array may be addressed through word lines and bit lines. A plurality of bit lines BL_1, BL_2, . . . BL_i, . . . BL_M (only two of which are shown in the figure) extending in a first direction may be arranged in a second direction to correspond to M rows, respectively. As described below, each bit line BL_i may be self-aligned with the corresponding row (i^{th} row). In addition, the word line may constitute a gate electrode of the selection transistor, and thus L layers of gate electrodes (only two of which are shown in the figure) may correspond to respective layers of selection transistors. The plurality of word lines in each layer extending in the second direction may be arranged in the first direction to correspond to N columns, respectively. For example, there are word lines WL_1-1, WL_2-1, . . . , WL_j-1, . . . , WL-N-1 (only two of which are shown in the figure) in the first layer; there are word lines WL_1-2, WL_2-2, . . . , WL_j-2, . . . , WL-N-2 (only two of which are shown in the figure) in the second layer; . . . ; there are word lines WL_1-k, WL_2-k, . . . , WL_j-k, . . . , WL-N-k (not shown in the figure) in the k^{th} layer; . . . ; there are word lines WL_1-L, WL_2-L, . . . , WL_j-L, . . . , WL-N-L (not shown in the figure) in the L^{th} layer. The word lines in each layer may be substantially coplanar.

According to an embodiment of the present disclosure, the bit lines may be located at the bottom of the array and may be substantially coplanar. From each bit line BL_i, a plurality of sub bit lines Sub_BL_i-1, Sub_BL_i-2, . . . , Sub_BL_i-j, . . . , Sub_BL_i-N may extend vertically to correspond to N columns, and thus may be connected to selection transistors (for example, the lower source/drain region as described below) of each column (the first to the N^{th} columns) in the corresponding row (i^{th} row) in each upper layer. The figure only shows two sub bit lines Sub_BL 1-1 and Sub_BL_1-2 extending from the bit line BL_1 as well as two sub bit lines Sub_BL_2-1 and Sub_BL_2-2 extending from the bit line BL_2.

Each selection transistor TR_i-j-k may be electrically connected to the corresponding bit line BL_i through the sub bit line Sub_BL_i-j. The gate electrode of the selection transistor is defined by a corresponding word line WL_j-k, and thus electrically connected between the word line WL_j-k and the bit line BL_i. Each selection transistor TR_i-j-k in the 3D array may be addressed through bit lines BL_i (1≤i≤M) and word lines WL_j-k (1≤j≤N, 1≤k≤L). Some contact portions, such as contact portions to the bit lines BL_1 and BL_2 and contact portions to the word lines WL_1-1 and WL_1-2, are schematically shown in FIG. 1(a). Through these contact portions, an electrical signal may be applied to address and access the selection transistor. Please note that for clarity in the illustration, the contact portions to the word lines WL_2-1 and WL_2-2 are not shown.

The sub bit line may be provided on one side of the corresponding column. For example, as shown in the figure, for each column (j^{th} column), the sub bit lines Sub_BL_i-j (1≤i≤M) that extend from each bit line may be electrically connected to the selection transistor in the column (j^{th} column) from one side of the column in the first direction. The sub bit lines Sub_BL_i-j (1≤i≤M) corresponding to the same column (j^{th} column) may be substantially aligned (e.g. substantially coplanar) in the second direction.

In addition, as shown in the figure, the sub bit lines may be provided in pairs. For example, for a certain column (such as the j^{th} column), its corresponding sub bit line Sub_BL_i-j (1≤i≤M) may be provided on a first side of the column (j^{th} column) in the first direction; while for a column (such as the (j+1)^{th} or (j−1)^{th} column) adjacent to the j^{th} column, its corresponding sub bit line Sub_BL_i-(j+1) or Sub_BL_i-(j−1) (1≤i≤M) may be provided on a second side of the column (the (j+1)^{th} or (j−1)^{th} column) in the first direction, and the second side is opposite to the first side. Therefore, the sub bit lines may be provided in pairs every two columns and every pair of sub bit lines are provided between adjacent columns. For example, sub bit lines Sub_BL_i-(2n−1) and Sub_BL_i-2n (1≤i≤M) may be provided between adjacent (2n−1)^{th} and (2n)^{th} columns (where n is a natural number greater than 0); no sub bit lines are provided between adjacent (2n)^{th} and (2n+1)^{th} columns; and sub bit lines Sub_BL_i-(2n+1) and Sub_BL_i-2(n+1) (1≤i≤M) may be provided between adjacent (2n+1)^{th} and (2(n+1))^{th} columns, and the like.

Each sub bit line Sub_BL_i-j may include a vertical extension portion VP extending vertically from a corresponding bit line BL_i and a lateral extension portion HP extending laterally from the vertical extension portion VP towards a corresponding selection transistor TR_i-j-k. Respective vertical extension portions VP of sub bit lines Sub_BL_i-(2n−1) and Sub_BL_i-2n provided in pairs may face each other, while respective lateral extension portions HP of sub bit lines Sub_BL_i-(2n−1) and Sub_BL_i-2n may extend in opposite directions.

The selection transistor TR_i-j-k may be a vertical device. The vertical device may include an active region provided on the substrate in a vertical direction (substantially a direction perpendicular to the surface of the substrate), and the active region includes source/drain regions (which may be referred to as an upper source/drain region and a lower source/drain region respectively) located at different vertical heights (such as at upper and lower ends of the active region), as well as a channel portion located between the upper and lower source/drain regions. A conductive channel may be formed between the upper and lower source/drain regions through a channel region formed in the channel portion. The active regions in the same layer may be substantially coplanar (for example, on a plane parallel to the surface of the substrate). The corresponding rows and columns in different layers may be substantially aligned with each other (for example, substantially coplanar) in the vertical direction.

Furthermore, the active region of each selection transistor TR_i-j-k may include a lower source/drain layer S/C_L, an upper source/drain layer S/C_U, and a channel layer CH including a part (which is used to define the above “channel portion”) extending between the lower source/drain layer S/C_L and the upper source/drain layer S/C_U. The lower source/drain region may include the lower source/drain layer S/C_L, for example, the lower source/drain region may be defined in the lower source/drain layer S/C_L through doping. Similarly, the upper source/drain region may include the upper source/drain layer S/C_U, for example, the upper source/drain region may be defined in the upper source/drain layer S/C_U through doping. Respective lower source/drain layers S/C_L of active regions of the selection transistors in M rows and N columns in each layer may be substantially coplanar, and respective upper source/drain layers S/C_U of active regions of the selection transistors in M rows and N columns in each layer may be substantially coplanar.

In the active region of each selection transistor TR_i-j-k, the channel layer CH may be an epitaxial layer formed on a sidewall of the lower source/drain layer S/C_L as well as a sidewall of the upper source/drain layer S/C_U (in the second direction). The channel layer CH may extend from the sidewall of the lower source/drain layer S/C_L to the sidewall of the upper source/drain layer S/C_U, so as to have the part (which is used to define the channel portion) extending between the lower source/drain layer S/C_L and the upper source/drain layer S/C_U. The channel layer CH may further extend to the sidewalls of sub site lines and bit lines, for example, when the sub site lines and bit lines include (doped) semiconductor materials. Therefore, when observed from the first direction, the active region may be in a C-shape, i.e., a shape in which the lower source/drain layer S/C_L and the upper source/drain layer S/C_U protrude from the channel layer CH.

As shown in the figures, respective C-shapes of the active regions of selection transistors of two adjacent rows may be opposite to each other. For example, for a certain row (such as the i^{th} row), the channel layer CH of the active region of the selection transistor in the row may be provided on a first side of the lower source/drain layer S/C_L and the upper source/drain layer S/C_U in the second direction; while in a row (such as the (i+1)^{th} or (i−1)^{th} row) adjacent to the certain row, the channel layer CH of the active region of the selection transistor in the row may be provided on a second side of the lower source/drain layer S/C_L and the upper source/drain layer S/C_U in the second direction, and the second side is opposite to the first side. Therefore, for each pair of adjacent columns, channel layers CH in respective active regions may be provided on sidewalls of corresponding lower source/drain layer S/C_L and upper source/drain layer S/C_U away from each other.

In the active region of each selection transistor TR_i-j-k, opposite end portions of the part of the channel layer CH extending between the lower source/drain layer S/C_L and the upper source/drain layer S/C_U in the first direction are recessed in the first direction relative to corresponding end portions of the lower source/drain layer S/C_L and corresponding end portions of the upper source/drain layer S/C_U. Such recess provides a space for the word line to bypass the channel portion to extend continuously in the second direction.

In the active region of each selection transistor TR_i-j-k, one end portion (which may be referred to as the “first end portion (of the lower source/drain layer S/C_L)”) of the lower source/drain layer S/C_L in the first direction may protrude in the first direction relative to a corresponding end portion (which may be referred to as the “first end portion (of the upper source/drain layer S/C_U)”) of the upper source/drain layer S/C_U, so as to be connected to the corresponding sub bit line, especially the lateral extension portion of the sub bit line. The lower source/drain layer S/C_L may be substantially aligned (e.g. substantially coplanar) with the lateral extension portion of the corresponding sub bit line. For selection transistors in the same column (e.g., the j^{th} column), first end portions of respective lower source/drain layers S/C_L may be substantially aligned (e.g. substantially coplanar), and first end portions of respective upper source/drain layers S/C_U may be substantially aligned (e.g. substantially coplanar). For selection transistors TR_i-j-k (1≤k≤L) in the same row (e.g., the i^{th} row) and the same column (e.g., the j^{th} column) in different layers, first end portions of respective lower source/drain layers S/C_L may be substantially aligned (e.g. substantially coplanar) in the vertical direction, and first end portions of respective upper source/drain layers S/C_U may be substantially aligned (e.g. substantially coplanar).

In the active region of each selection transistor TR_i-j-k, another end portion (which may be referred to as the “second end portion (of the lower source/drain layer S/C_L)”) of the lower source/drain layer S/C_L in the first direction may be substantially aligned with a corresponding end portion (which may be referred to as the “second end portion (of the upper source/drain layer S/C_U)”) of the upper source/drain layer S/C_U in the vertical direction. For selection transistors in the same column (e.g., the j^{th} column), second end portions of respective lower source/drain layers S/C_L may be substantially aligned (e.g. substantially coplanar) with second end portions of respective upper source/drain layers S/C_U. Second end portions of lower source/drain layers S/C_L and upper source/drain layers S/C_U of selection transistors in a lower layer may protrude relative to second end portions of lower source/drain layers S/C_L and upper source/drain layers S/C_U of selection transistors located in the same row and the same column in an upper layer. Therefore, for selection transistors TR_i-j-k (1≤k≤L) in the same row (e.g., the i^{th} row) and the same column (e.g., the j^{th} column), second end portions of lower source/drain layers S/C_L and upper source/drain layers S/C_U of respective active regions may form a step structure. Such step structure is conducive to forming the contact portion to the active region (especially the upper source/drain layer S/C_U) in each layer, for example, the (protruding) second end portion of each upper source/drain layer S/C_U may be used as a landing pad for the contact portion. In FIG. 1(a), for the sake of illustration convenience, only contact portions to (respective upper source/drain layers S/C_U of) transistors TR_2-2-1 and TR_2-2-2 are shown.

The word line WL_j-k may extend in the second direction to surround at least part of a periphery of the channel portion of the selection transistor TR_i-j-k (1≤i≤M), so as to overlap with at least one side of the channel portion and thus form a gate electrode of the selection transistor TR_i-j-k. In FIG. 1(a), in order to clearly illustrate the structure of the word line surrounding the channel portion, the word lines WL_2-1 and WL_2-2 are only partially shown to reveal the channel portion surrounded by the word lines. The word line WL_j-k may surround the periphery of the channel portion of the selection transistor, so as to form a Gate-All-Around (GAA) configuration.

According to another embodiment, the word line WL_j-k may surround one side (or multiple sides) of the periphery of the channel portion, rather than the other side (or multiple sides) of the periphery of the channel portion, and thus may form a single side device. For example, the word line WL_j-k may extend between the channel portions of adjacent selection transistors with C-shaped openings facing each other in the corresponding column (j^{th} column), so as to bypass opposite end portions of these channel portions in the first direction to extend in the second direction. The word line WL_j-k does not extend between the channel portions of adjacent selection transistors with C-shaped openings away from each other. This will be further described in detail below.

Such memory device may be manufactured as follows.

A stack including two or more device layers (such as L layers as described above) may be provided on the substrate. Each device layer, which may be used to define an array of selection transistors (e.g., M rows×N columns as described above) at a corresponding level, for example, may include a first source/drain layer, a channel defining layer, and a second source/drain layer sequentially stacked. In addition, for the isolation between devices, an isolation defining layer may be provided between device layers. The isolation defining layer may be replaced with an isolation material in subsequent processes. Such vertically stacked device layer may then define a 3D array of selection transistors (e.g. the 3D array of M×N×L as described above).

Each selection transistor may be electrically connected to a memory element such as a capacitor or MTJ at one end, and may be electrically connected to a bit line at the other end, so as to receive data (e.g., write data) from the bit line or send data (e.g., read data) to the bit line. According to embodiments of the present disclosure, a sub bit line may be provided on one side of the selection transistor to electrically connect the selection transistor to the corresponding bit line, and a contact portion may be provided on the other side of the selection transistor to electrically connect the selection transistor to the corresponding memory element.

In order to provide the sub bit line, a plurality of first processing channels extending vertically may be formed in the stack. The plurality of first processing channels may be arranged in the first direction (such as a direction in which the bit line extends), and extend in the second direction (such as a direction in which the word line extends) that intersects with (such as perpendicular to) the first direction. Considering that each selection transistor requires the sub bit line only on one side, a first processing channel may be provided at a region of every two columns of selection transistors, so that each column of selection transistors may be adjacent to the first processing channel only on one side. Considering the electrical connection between the bit line and the selection transistor, for the lowermost device layer, one (e.g., the first source/drain layer) of the first source/drain layer and the second source/drain layer may constitute the bit line through subsequent processes. Therefore, a bottom of the first processing channel may be defined by the first source/drain layer of the lowermost device layer. The present disclosure is not limited to this. Such bit line may be provided separately.

The sub bit line may be formed, through a spacer formation process, along a sidewall of the first processing channel on the first source/drain layer of the lowermost device layer, thus it may be self-aligned. Before forming the sub bit line, the second source/drain layer in each device layer exposed in the first processing channel may be recessed in the first direction relative to the first source/drain layer via the first processing channel, so that the sub bit line formed along the sidewall of the first processing channel may only be in contact with the first source/drain layer and thus electrically connected to the first source/drain layer, while being separated from the second source/drain layer and electrically isolated from each other (due to the subsequently filled dielectric).

In addition, an end portion of the channel defining layer in each device layer in the first direction is recessed, via the first processing channel, in the first direction relative to a corresponding end portion of the first source/drain layer and a corresponding end portion of the second source/drain layer, and a first gate position retaining layer is formed in a resulting recess. The first gate position retaining layer may provide a space where the word line bypasses the channel portion to extend continuously in the second direction subsequently.

In addition, a part of the isolation defining layer facing the first processing channel is replaced, via the first processing channel, with an isolation layer.

Each column of selection transistors may have sub bit lines on one side in the first direction. Each column of selection transistors may be processed on the other side in the first direction, so as to provide the contact portion electrically connected to the memory element.

A plurality of second processing channels extending vertically may be formed in the stack. The plurality of second processing channels may be arranged alternately with the first processing channels in the first direction (the first processing channels may be filled when forming the second processing channels to avoid affecting the already formed structures such as the sub bit lines in the first processing channels), and extend in the second direction. For example, the second processing channel may be provided substantially in the middle between every two adjacent first processing channels. When forming the second processing channel, a step structure formation process may be used, so that the device layers in the stack may form a step structure at the second processing channel, so that the lower device layer protrudes in the first direction relative to the upper device layer to form a step. For example, the step structure may be formed by combining photoresist trimming with sequential etching.

Similarly, an end portion of the channel defining layer in each device layer in the first direction is recessed, via the second processing channel, in the first direction relative to a corresponding end portion of the first source/drain layer and a corresponding end portion of the second source/drain layer, and a second gate position retaining layer is formed in a resulting recess. The second gate position retaining layer may provide a space where the word line bypasses the channel portion to extend continuously in the second direction subsequently.

Similarly, a remaining part of the isolation defining layer facing the second processing channel is replaced, via the second processing channel, with an isolation layer. An interface or a boundary may exist between the isolation layer replaced via the first processing channel and the isolation layer replaced via the second processing channel.

In the above process, the first processing channel and the second processing channel do not pass through the stack, but may stop at the first source/drain layer of the lowermost device layer to ensure the continuity of the first source/drain layer in the first direction, so that the first source/drain layer of the lowermost device layer may then be used as the bit line.

In this way, each device layer is divided into a plurality of columns arranged in the first direction through the first processing channels and the second processing channels (which may be filled to prevent subsequent processing from affecting the already formed structures such as the sub bit line, the step structure, etc.), and each column extends in the second direction. Next, each device layer may be divided in the second direction to form an array of rows and columns.

For example, a plurality of third processing channels that pass through the stack may be formed. The plurality of third processing channels are arranged in the second direction and extend in the first direction. A channel layer may be formed, by selective epitaxial growth, on a sidewall of each device layer exposed in the third processing channel. Due to the selective epitaxial growth, the channel layer may maintain a shape substantially identical to the sidewall of the device layer exposed in the third processing channel. A part of the channel layer growing on the sidewall of the channel defining layer may define the channel portion. The channel layer may be in a form of nanosheet.

A plurality of fourth processing channels that pass through the stack may be formed. The plurality of fourth processing channels are arranged alternately with the third processing channels in the second direction and extend in the first direction. The channel defining layer, the first gate position retaining layer, and the second gate position retaining layer may be removed via the fourth processing channel. In this way, a gate accommodating space (a space released due to the removal of the channel defining layer, the first gate position retaining layer, and the second gate position retaining layer, as well as the third and fourth processing channels) is left around the channel portion.

A word line layer corresponding to each device layer may be formed on the substrate. For example, an interlayer dielectric layer and a gate conductor layer may be alternately formed, where each gate conductor layer may be located at a height corresponding to the channel portion in each device layer. Each gate conductor layer may be patterned (together or separately) as a word line extending in the second direction, so as to at least partially surround a periphery of the channel portion (via the gate dielectric layer).

The present disclosure may be presented in various forms, and some examples of which will be described below. In the following description, the selection of various materials is involved. In selecting the materials, etching selectivity is considered in addition to the function of the materials (for example, a semiconductor material is used to form the active region, a dielectric material is used to form an electrical isolation, and a conductive material is used to form an electrode, an interconnection structure, etc.). In the following description, the required etching selectivity may or may not be indicated. It should be clear to those skilled in the art that when etching a certain material layer is mentioned below, if it is not mentioned that other layers are also etched or the drawing does not show that other layers are also etched, then such etching may be selective, and the material layer may have etching selectivity relative to other layers exposed to the same etching formula.

FIGS. 2 to 46(b) show schematic diagrams of some stages in a process of manufacturing a memory device according to an embodiment of the present disclosure.

As shown in FIG. 2, a substrate 1001 is provided. The substrate 1001 may be a substrate in any form, including but not limited to, a bulk semiconductor material substrate such as a bulk Si substrate, a Semiconductor On Insulator (SOI) substrate, a compound semiconductor substrate such as a SiGe substrate, or the like. Hereinafter, the bulk Si substrate, such as a Si wafer, will be described by way of example for the convenience of description.

A memory device, for example, a non-volatile memory device such as DRAM or MRAM, may be formed on the substrate 1001 as follows. A memory cell in the memory device may include a selection transistor as an n-type device or a p-type device, as well as a capacitor or a magnetic tunnel junction (MTJ) as a memory element. Here, taking the n-type selection transistor as an example, a p-type well (not shown) may be formed in the substrate 1001. Therefore, the following description, especially regarding doping types, pertains to the formation of the n-type selection transistor. However, the present disclosure is not limited to this.

A first device layer L1, a second device layer L2, and a third device layer L3 may be formed on the substrate 1001 by epitaxial growth, for example. The active region of the selection transistor may be defined from each device layer L1, L2 or L3. For example, the first device layer L1 may include a first source/drain layer 1003₁, a channel defining layer 1005₁, and a second source/drain layer 1007₁. Similarly, the second device layer L2 may include a first source/drain layer 1003₂, a channel defining layer 1005₂, and a second source/drain layer 1007₂. The third device layer L3 may include a first source/drain layer 1003₃, a channel defining layer 1005₃, and a second source/drain layer 1007₃. In addition, for the purpose of subsequent electrical isolation, isolation defining layers 1009₁, 1009₂, and 1009₃ may be provided between the device layers L1, L2 and L3. These semiconductor layers may have good crystal quality and may be single crystal structures. There may be a clear crystal interface between adjacent semiconductor layers.

These semiconductor layers may include various suitable semiconductor materials, for example, element semiconductor materials such as Group IV element semiconductor materials such as Si or Ge, compound semiconductor materials such as Group IV compound semiconductor materials such as SiGe, or Group III-V compound semiconductor materials such as InP and GaAs. The material of the semiconductor layer may be selected based on factors such as substrate properties and device performance to be achieved.

In this embodiment, the semiconductor layers formed on the Si wafer may be Si-based materials. Furthermore, considering the subsequent process, adjacent semiconductor layers may have etching selectivity relative to each other. For example, the source/drain layer may include Si, while the channel defining layer and the isolation defining layer may include SiGe (for example, the atomic percentage of Ge may be in a range of about 10% to 30%).

The semiconductor layers in each device layer may be appropriately doped according to the conductivity type of the selection transistor to be formed. For example, the first source/drain layer and the second source/drain layer may be heavily doped (e.g., with a doping concentration in a range of about 1E19 cm⁻³ to 1E21 cm⁻³) to be of the same conductivity type as the selection transistor to be implemented. Alternatively, for tunneling devices, the first source/drain layer and the second source/drain layer in the same device layer may be doped to opposite conductivity types. The doping of semiconductor layers may be achieved through in-situ doping during epitaxial growth, or through other doping methods such as ion implantation. There may be a doping concentration interface between adjacent semiconductor layers.

Each semiconductor layer may have an appropriate thickness (in the vertical direction). For example, both the first and second source/drain layers may have a thickness in a range of about 20 nm to 200 nm, the isolation defining layer may have a thickness in a range of about 10 nm to 30 nm, and the channel defining layer may have a thickness in a range of about 20 nm to 50 nm. Considering the subsequent process, the thickness of the channel defining layer may be greater than that of the isolation defining layer, and the thickness of the lower first source/drain layer of each device layer (except for the lowermost device layer L1) may be less than the thickness of the upper second source/drain layer of the device layer.

In addition, a hard mask layer 1011 may be formed on the semiconductor layer, so as to assist in patterning. For example, the hard mask layer 1011 may include nitride (such as silicon nitride) with a thickness in a range of about 30 nm to 100 nm.

Three device layers L1, L2, and L3 are shown in FIG. 2, and three layers of selection transistors may be subsequently formed. However, the present disclosure is not limited to this. More or fewer device layers (such as L layers described above) may be provided, and corresponding layers of selection transistors may be formed.

A sub bit line extending vertically may be fabricated to electrically connect vertically stacked selection transistors to a corresponding bit line.

For example, as shown in FIGS. 3(a) and 3(b), a photoresist 1013 may be formed on the hard mask layer 1011 and patterned by photolithography as a series of openings arranged in the first direction (e.g., x direction) and extending in the second direction (e.g., y direction) intersecting with (e.g., perpendicular to) the first direction. Such openings define positions of the sub bit lines.

As shown in FIG. 4, the patterned photoresist 1013 may be used as an etching mask to etch each layer on the substrate 1001 through anisotropic etching such as reactive ion etching (RIE) in the vertical direction (e.g. a direction perpendicular to the surface of the substrate), so as to form a first processing channel T1. RIE may stop at the first source/drain layer 10031 of the lowermost device layer L1. Therefore, a series of vertical first processing channels T1 are left on the substrate 1001. Afterwards, the photoresist 1013 may be removed.

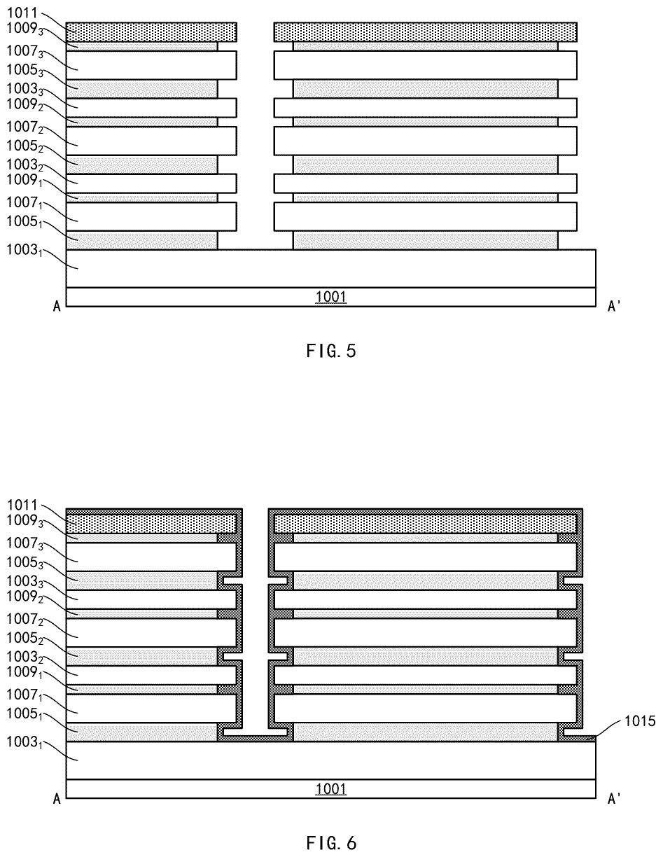

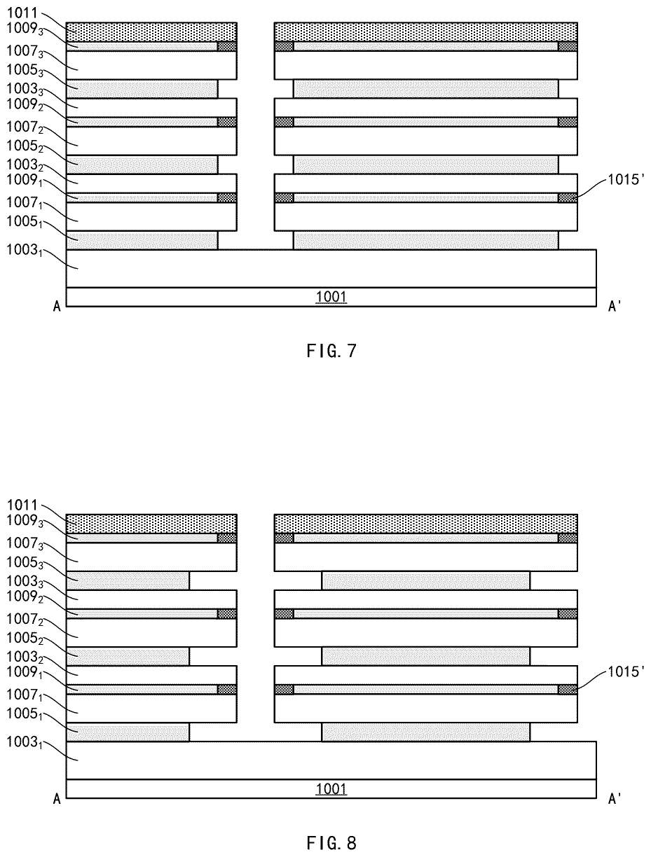

A gate position retaining layer may be formed at end portions of the channel defining layers 1005₁, 1005₂, and 1005₃ in the first direction (e.g. x direction). For example, as shown in FIG. 5, via the first processing channel T1, the channel defining layers 1005₁, 1005₂, and 1005₃ (in this example, SiGe) in respective device layers may be recessed in the first direction relative to respective source/drain layers (in this example, Si) through selective etching, so as to provide a space for accommodating a gate stack subsequently. In this example, the isolation defining layers 1009₁, 1009₂, and 1009₃ (in this example, which is SiGe, same as the channel defining layer) may also be relatively recessed by substantially the same extent in the first direction. Considering the formation of a plug (please refer to 1015′ in FIG. 7), the etching depth (or relative recess extent) may be greater than half of the maximum one of thicknesses of the isolation defining layers 1009₁, 1009₂, and 1009₃.

To avoid the formation of the gate position retaining layer in the relative recesses of the isolation defining layers 1009₁, 1009₂, and 1009₃ (which is not desirable), a plug may be formed in the relative recesses of the isolation defining layers 1009₁, 1009₂, and 1009₃. For example, as shown in FIG. 6, a plug material layer 1015 with a thickness greater than half of the maximum one of thicknesses of the isolation defining layers 1009₁, 1009₂, and 1009₃ and less than half of the minimum one of thicknesses of the channel defining layers 1005₁, 1005₂, and 1005₃ may be deposited. Therefore, the relative recesses of the isolation defining layers 1009₁, 1009₂, and 1009₃ may be fully filled with the deposited plug material layer 1015, while the deposited plug material layer 1015 may maintain in a substantially conformal form of thin film in the relative recesses of the channel defining layers 1005₁, 1005₂, and 1005₃. Considering the etching selectivity in subsequent processes, the plug material layer 1015 may include, for example, SiC. The deposited plug material layer 1015 may be etched back by a certain thickness (for example, slightly greater than the deposited thickness), so that the plug material layer 1015 may be left in the relative recesses of the isolation defining layers 1009₁, 1009₂, and 1009₃ to form a plug 1015′, while removed from the relative recesses of the channel defining layers 1005₁, 1005₂, and 1005₃, as shown in FIG. 7. To better control the etching depth, atomic layer etching (ALE) may be used.

In a case that the isolation defining layers 1009₁, 1009₂, and 1009₃ have etching selectivity relative to the channel defining layers 1005₁, 1005₂, and 1005₃, the formation of the plug 1015′ may be omitted.

In addition, as shown in FIG. 8, via the first processing channel T1, the channel defining layers 1005₁, 1005₂, and 1005₃ in respective device layers may be further recessed in the first direction through selectively etching by, for example, about 10 nm to 40 nm, so as to provide a larger gate accommodating space. In the selective etching step described above in conjunction with FIG. 5, the channel defining layers 1005₁, 1005₂, and 1005₃ (as well as the isolation defining layers 1009₁, 1009₂, and 1009₃) are not recessed so much in order to facilitate the formation of the plug 1015′, as excessive recess may lead to difficulties in conformal deposition and etching back of the plug material layer 1015 in such recess.

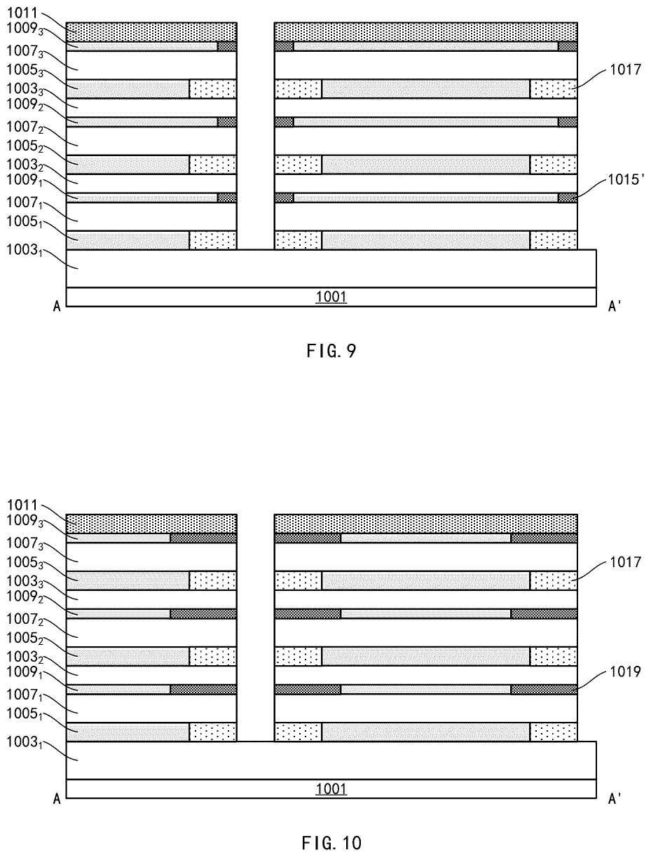

Afterwards, as shown in FIG. 9, a gate position retaining layer 1017 (which may be referred to as the “first gate position retaining layer”) may be formed in the relative recesses of channel defining layers 1005₁, 1005₂, and 1005₃. The first gate position retaining layer 1017 may include a material having etching selectivity relative to the plug 1015′ (in this example, SiC) and the hard mask layer 1011 (in this example, nitride), such as oxide (such as silicon oxide). For example, oxide may be deposited, and RIE in the vertical direction may be performed on the deposited oxide to form the first gate position retaining layer 1017.

Similarly, as shown in FIG. 10, the plug 1015′ in the relative recesses of the isolation defining layers 1009₁, 1009₂, and 1009₃ may be removed by selective etching via the first processing channel T1, and the exposed isolation defining layers 1009₁, 1009₂, and 1009₃ may be further recessed in the first direction by, for example, about 15 nm to 60 nm. In addition, a plug 1019 may be formed in the further recesses of the isolation defining layers 1009₁, 1009₂, and 1009₃ by depositing and etching back. Considering etching selectivity, the plug 1019 may include SiC.

At present, the sidewalls of the first source/drain layer and the second source/drain layer in each device layer are exposed in the first processing channel T1. The desired sub bit line is connected to a source/drain region defined by one (e.g., the first source/drain layer) of the first source/drain layer and the second source/drain layer, rather than a source/drain region (which may be connected to the memory element such as capacitor, MTJ, etc.) defined by the other (e.g., the second source/drain layer) of the first source/drain layer and the second source/drain layer. Therefore, the second source/drain layer may be recessed in the first direction relative to the first source/drain layer, for example.

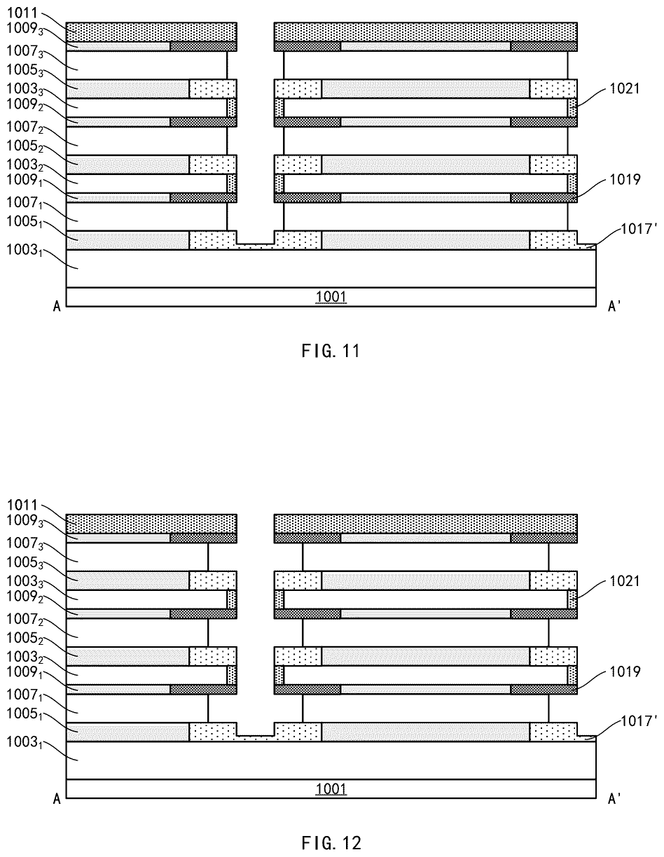

To achieve relative recess between the first source/drain layer and the second source/drain layer which do not have etching selectivity relative to each other, a plug 1021 may be formed at the end portions of the first source/drain layers 1003₂ and 1003₃ that are desired to protrude relatively (so as to be connected to the sub bit line) by a process similar to that described in combination with FIGS. 6 and 7 above, as shown in FIG. 11. As the thicknesses of the first source/drain layers 1003₂ and 1003₃ in respective device layers (except for the lowermost device layer L1) is less than the thicknesses of the second source/drain layers 1007₂ and 1007₃ as described above, the plug 1021 may be formed. Considering the etching selectivity in subsequent processes, the plug 1021 may include nitride. In addition, an etch stop layer (not shown) such as oxide may be provided between the plug 1021 of nitride and the source/drain layer. As described above, if the first source/drain layer and the second source/drain layer have etching selectivity relative to each other, the formation of the plug 1021 may also be omitted.

In order to prevent the etching in the process of forming the plug 1021 from affecting the first source/drain layer 1003₁ in the lowermost device layer L1, a protective layer may be formed at the bottom of the first processing channel T1 before starting the process of forming the plug 1021. For example, oxide may be deposited to fully fill the first processing channel T1, planarization such as chemical mechanical polishing (CMP, which may stop at the hard mask layer 1011) may be performed on the deposited oxide, and then the planarized oxide may be etched back by RIE in the vertical direction, so that a top surface of the oxide may be lowered to expose the sidewalls of the source/drain layers except for the first source/drain layer 1003₁ in the lowermost device layer L1 (for example, the top surface of the oxide is at a height between the top surface and bottom surface of the first channel defining layer 1005₁ in the lowermost device layer L1). In this example, both the oxide thus formed and the previously formed gate position retaining layer 1017 include oxides, and thus are integrated as 1017′.

As shown in FIG. 12, via the first processing channel T1, the second source/drain layers 1007₁, 1007₂, and 1007₃ in respective device layers may be further recessed in the first direction by, for example, about 10 nm to 30 nm. In this way, the second source/drain layers 1007₁, 1007₂, and 1007₃ are recessed in the first direction relative to the first source/drain layers 1003₁, 1003₂, and 1003₃. In addition, the second source/drain layers 1007₁, 1007₂, and 1007₃ may still protrude relative to the channel defining layers 1005₁, 1005₂, and 1005₃, so as to define the gate accommodating space on the outer side of the end portions of the channel defining layers 1005₁, 1005₂, and 1005₃ along with the first source/drain layers 1003₁, 1003₂, and 1003₃.

After patterning the end portion of each device layer on the side of the first processing channel T1 as described above, sub bit lines may be formed in the first processing channel T1.

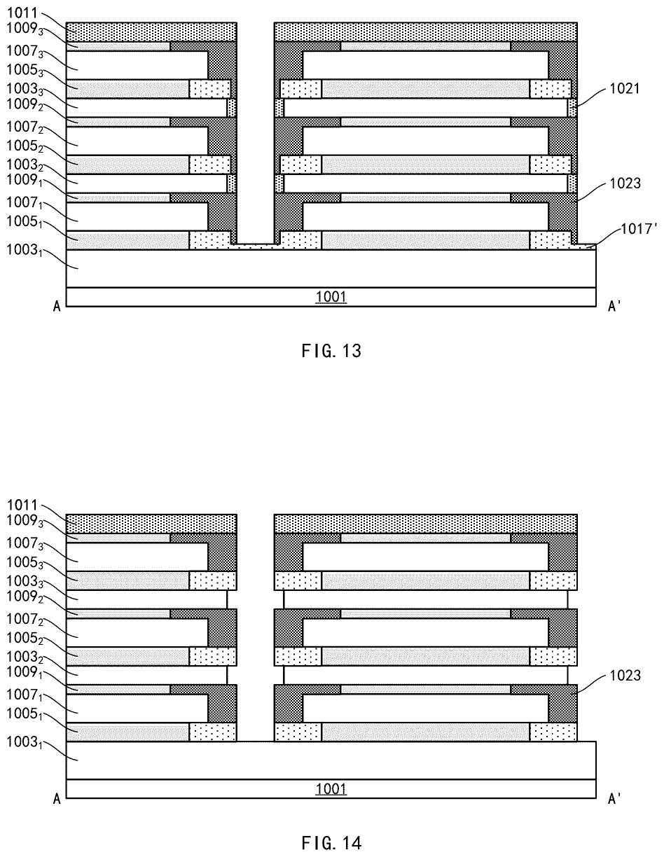

As shown in FIG. 13, a gap below the hard mask layer 1011 caused by patterning the device layers may be filled with a dielectric material. For example, an isolation layer 1023 may be formed by depositing and etching back (e.g. RIE in the vertical direction) SiC. For example, before depositing SiC, the first gate position retaining layer 1017 may be etched slightly (so as to be recessed by a certain depth in the first direction) by selectively etching. In this way, the subsequently formed isolation layer 1023 may cover the sidewall of the first gate position retaining layer 1017. This may increase the electrical distance between the gate stack that subsequently replaces the first gate position retaining layer 1017 and the sub bit lines formed in the first processing channel T1, and thus reduce parasitic capacitance. In the following illustrations and descriptions, for convenience only, the case of not etching the first gate position retaining layer 1017 is taken as an example.

As shown in FIG. 14, the plug 1021 may be removed by selective etching to expose the sidewalls of the first source/drain layers 1003₂ and 1003₃ in the device layers L2 and L3 (so as to be connected to the subsequently formed sub bit lines). In addition, the protective layer 1017′ at the bottom of the first processing channel T1 may be removed by selective etching, such as RIE in the vertical direction, so that the first source/drain layer 10031 of the lowermost device layer L1 is exposed at the bottom of the first processing channel T1 (and the first gate position retaining layer 1017 is still left at the end portion of each channel defining layer).

According to an embodiment of the present disclosure, the sub bit line may be formed in a self-alignment way.

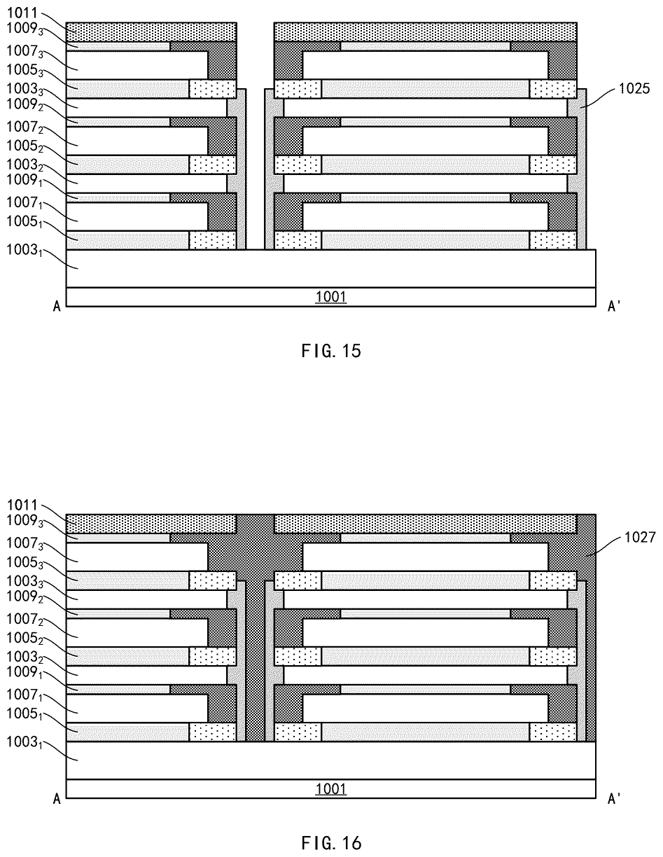

For example, as shown in FIG. 15, a sub bit line 1025 that extends along the sidewall of the first processing channel T1 may be formed through a spacer formation process. For example, a layer of conductive material such as doped polycrystalline silicon may be deposited in a substantially conformal manner, and then anisotropic etching, such as RIE in the vertical direction, may be performed on the deposited conductive material to remove a lateral extension portion of the deposited conductive material and leave a vertical extension portion of the deposited conductive material, so as to form the sub bit line 1025 in a spacer form. Here, due to the relative recesses of the sidewalls of the first source/drain layers 1003₂ and 1003₃, the sub bit line 1025 protrudes correspondingly to be in contact with the sidewalls of the first source/drain layers 1003₂ and 1003₃ in the device layers L2 and L3. In addition, the sub bit line 1025 is in contact with the first source/drain layer 1003₁ of the lowermost device layer L1 at the bottom. Therefore, the sub bit line 1025 may be in contact with the first source/drain layers 1003₁, 1003₂, and 1003₃ in respective device layers.

Afterwards, as shown in FIG. 16, the first processing channel T1 may be backfilled by depositing and planarizing a dielectric material, so as to achieve an electrical isolation between the device layers on opposite sides of the first processing channel T1. For example, the deposited dielectric material may include the same material (in this example, SiC) as the isolation layer 1023, and thus be integrated as 1027.

The first source/drain layer in each device layer that defines the lower source/drain region is connected to the sub bit line. In DRAM, the second source/drain layer that defines the upper source/drain region may be connected to the memory element such as the capacitor, MTJ, etc., so as to implement the memory cell. Considering the vertical stack configuration of device layers, a step structure may be formed to achieve an electrical connection to the device layer (especially the second source/drain layer) corresponding to the memory element. For example, such step structure may be formed on the side of each device layer opposite to the side where sub bit lines are formed in the first direction.

Multiple methods may be used to form the step structure. For example, photoresist trimming combined with sequential etching may be used to pattern the step structure. When patterning, the device layer L1, L2, or L3 may be considered as “one layer”, and a step may be formed between the first device layer L1 and the second device layer L2, as well as a step may be formed between the second device layer L2 and the third device layer L3.

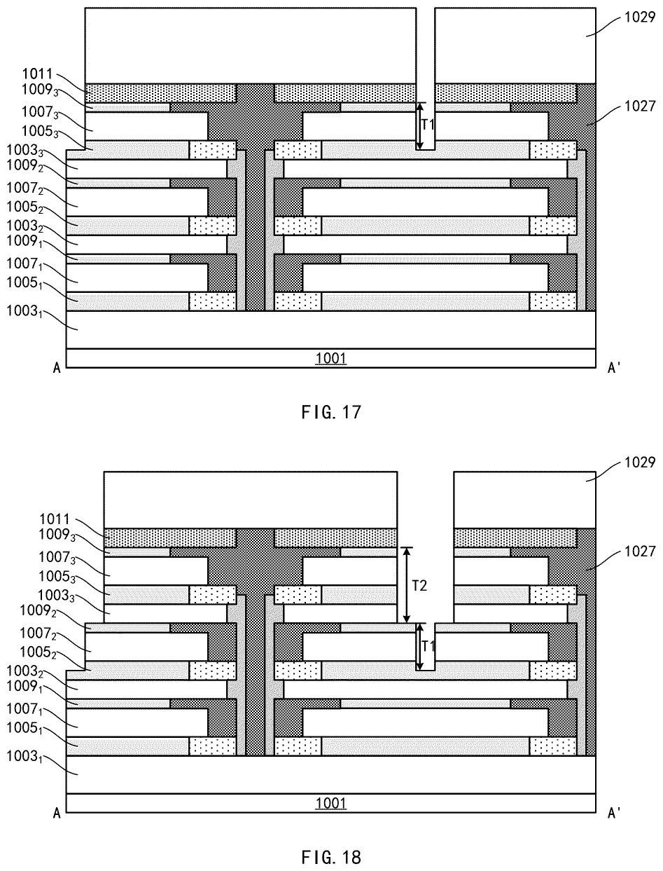

For example, as shown in FIG. 17, a photoresist 1029 may be formed on the hard mask layer 1011 and patterned by photolithography as a series of openings arranged in the first direction (e.g. x direction) and extending in the second direction (e.g. y direction), which may define the position of the step structure. The opening in the photoresist 1029 may be located between every pair of adjacent first processing channels T1 (which have been filled back) in the first direction, for example, substantially at the center.

The patterned photoresist 1029 may be used as a mask to etch the hard mask layer 1011 downwards to expose the lower device layer, and then etch the device layer. When etching the device layer, an etching formula that is substantially non selective relative to each layer (such as Si and SiGe) in the device layer may be selected. Here, an etching depth D1 may be controlled to correspond to the thickness (i.e., a sum of the thickness of the channel defining layer 1005₁ and the thickness of the second source/drain layer 1007₁) of the first device layer L1 (except for the first source/drain layer 1003₁, as the first source/drain layer 1003₁ does not need to be etched).

Afterwards, as shown in FIG. 18, the photoresist 1029 may be trimmed. For example, the width of the opening in the photoresist 1029 in the first direction may be increased, and the increase amplitude may correspond to the width of the desired step in the first direction. The trimmed photoresist 1029 may be used as a mask to continue to etch the device layer. Similarly, an etching depth D2 may be controlled to correspond to the thickness (i.e., a sum of the thickness of the first source/drain layer 1003₂ and the thickness of the channel defining layer 1005₂ and the thickness of the second source/drain layer 1007₂) of the second device layer L2 plus the thickness of the isolation defining layer 1009₁ (because the isolation defining layer 1009₁ may be recessed relative to the lower first device layer L1 like the second device layer L2, so as to expose the lower first device layer L1).

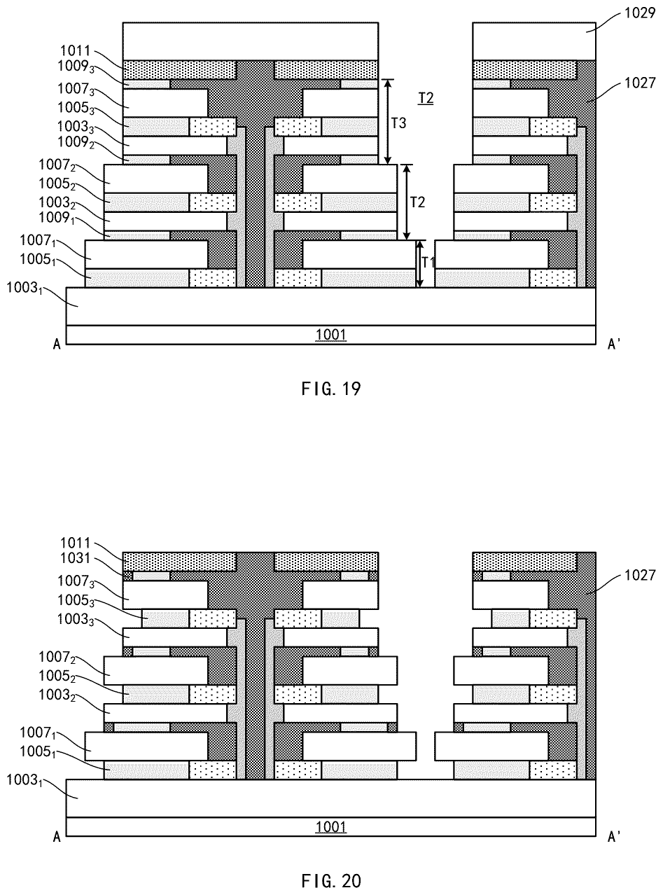

Similarly, as shown in FIG. 19, the photoresist 1029 may be further trimmed, so that the width of the opening in the photoresist 1029 in the first direction may be increased, and the increase amplitude may correspond to the width of the desired step in the first direction. The trimmed photoresist 1029 may be used as a mask to continue to etch the device layer. Similarly, an etching depth D3 may be controlled to correspond to the thickness (i.e., a sum of the thickness of the first source/drain layer 1003₃ and the thickness of the channel defining layer 1005₃ and the thickness of the second source/drain layer 1007₃) of the third device layer L3 plus the thickness of the isolation defining layer 1009₂ (because the isolation defining layer 1009₂ may be recessed relative to the lower second device layer L2 like the third device layer L3, so as to expose the lower second device layer L2) plus the thickness of the isolation defining layer 1009₃ (because the isolation defining layer 1009₃ may be recessed relative to the lower second device layer L2 like the third device layer L3, so as to expose the lower second device layer L2).

Therefore, the step structure is formed in the device layer. As shown in FIG. 19, the lower device layer protrudes in the first direction relative to the upper device layer, so as to form the step. The protruding part of the lower device layer relative to the upper device layer may then be used as a landing pad of a contact portion to the device layer (especially the second source/drain layer).

In a case of more layers, the photoresist may be trimmed similarly, and the device layers may be sequentially etched according to the thicknesses of these device layers (and if necessary, adding a thickness of the corresponding isolation defining layer) so as to form more steps. Afterwards, the photoresist 1029 may be removed.

In addition, due to the above process, a second processing channel T2 passing through each device layer (except for the first source/drain layer 1003₁ of the lowermost device layer L1) in the vertical direction is formed. Therefore, each device layer (except for the first source/drain layer 1003₁ of the lowermost device layer L1) is divided into parts separated from each other in the first direction by the second processing channel T2 and the first processing channel T1 (filled with the isolation layer), that is, a plurality of columns extending in the second direction arranged in the first direction (such as N columns as described above). Each column has a sub bit line on one side in the first direction and a step structure on the opposite side.

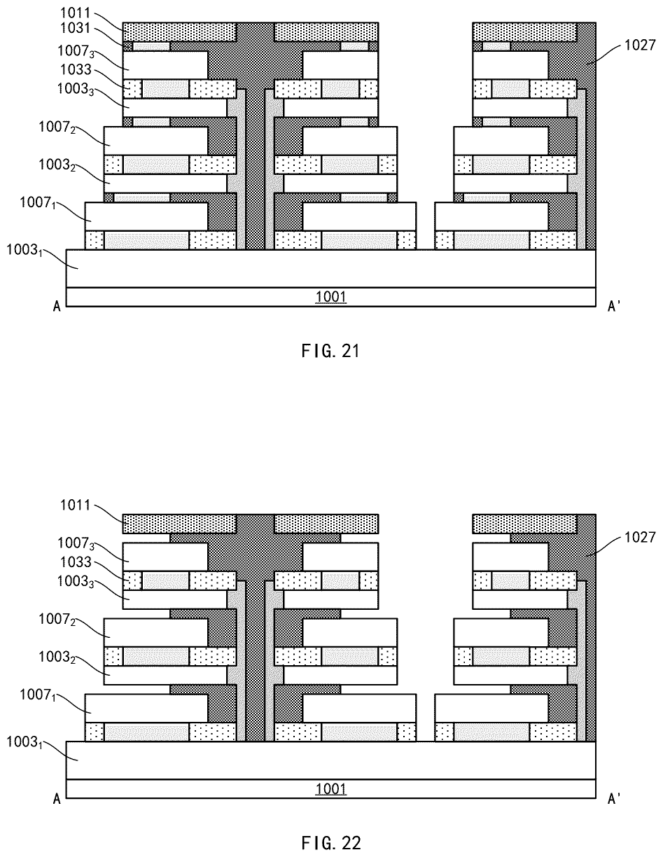

Similarly, as shown in FIG. 20, via the second processing channel T2, the channel defining layers 1005₁, 1005₂, and 1005₃ (in this example, SiGe) in respective device layers may be recessed in the first direction relative to respective source/drain layers (in this example, Si) through selective etching, so as to provide a space for accommodating a gate stack subsequently. As described above in combination with FIGS. 5 to 8, a plug 1031 may be formed to prevent the subsequent formed second gate position retaining layer (please refer to 1033 in FIG. 21) from also forming at the end portions of the isolation defining layers 1009₁, 1009₂, and 1009₃.

Afterwards, as shown in FIG. 21, a second gate position retaining layer 1033 may be formed in the relative recesses of channel defining layers 1005₁, 1005₂, and 1005₃ by depositing followed by etching back, such as oxide. Therefore, the first gate position retaining layer 1017 and the second gate position retaining layer 1033 are formed respectively at opposite ends of the channel defining layers 1005₁, 1005₂, and 1005₃ in the first direction. This helps the subsequently formed word line to bypass the channel layer and extend continuously in the second direction, and also helps to form the GAA configuration.

The isolation defining layer may be replaced with an isolation material to achieve electrical isolation between device layers adjacent in the vertical direction. For example, as shown in FIG. 22, the plug 1031 may be removed by selective etching to expose the isolation defining layers 1009₁, 1009₂, and 1009₃. Then, the isolation defining layers 1009₁, 1009₂, and 1009₃ may be removed by selective etching. As shown in FIG. 24, a space left due to the removal of isolation defining layers 1009₁, 1009₂, and 1009₃ may be filled with the isolation material by depositing followed by etching back (for example, RIE in the vertical direction). For example, the filled isolation material may also include SiC as the previous isolation layer 1027, and thus be integrated as 1037. Note that between the device layers, the isolation layer 1037 may include dielectric interfaces or boundaries, as shown by the dashed lines in FIG. 24. This is because the isolation layers between device layers may be filled separately from the first processing channel T1 and the second processing channel T2. For convenience, such dielectric interfaces or boundaries are no longer shown in other figures.

For example, before filling the isolation material, in order to reduce contact resistance, the surfaces of the first source/drain layer and the second source/drain layer of each device layer exposed to the outside may be silicified via the second processing channel T2 to form a silicide 1035. For example, a metal such as Ni or NiPt may be deposited and annealed at a temperature in a range of about 300° C. to 700° C., so that the deposited metal reacts with semiconductor elements in the first source/drain layer and the second source/drain layer, so as to generate a metal semiconductor compound such as NiSi or NiPtSi. Therefore, the silicide 1035 may be formed on a sidewall of the first source/drain layer on a side of the second processing channel T2 and a part of the lower surface of the first source/drain layer, as well as on a sidewall of the second source/drain layer on a side of the second processing channel T2 and a part of the upper surface of the second source/drain layer. Afterwards, the unreacted remaining metal may be removed and the isolation layer 1037 may be formed as described above.

Similarly, as shown in FIGS. 25(a) to 25(d), the second processing channel T2 may be backfilled by depositing and planarizing a dielectric material. Here, the deposited dielectric material may include the same material (in this example, SiC) as the isolation layer 1037, and is thus integrated as 1039. In addition, before depositing the dielectric material, the hard mask layer 1011 may be removed by selective etching such as RIE. This is because the separation of device layers in the first direction (separated into N columns) has been achieved using the hard mask layer 1011.

In addition, in the following process, a spacer image transfer technology is used to achieve finer patterns. For this purpose, a mandrel layer 1041 may be formed on the isolation layer 1039 by deposition, for example. Considering etching selectivity, the mandrel layer 1041 may include (polycrystalline) silicon. On the mandrel layer 1041, an additional hard mask layer 1043 may be formed to assist in patterning, particularly in separating device layers in the second direction (e.g., y direction). For example, the hard mask layer 1043 may include a nitride with a thickness in a range of about 30 nm to 100 nm.

A photoresist 1045 may be formed on the hard mask layer 1043 and patterned by photolithography as a series of lines extending in the first direction (e.g. x direction) arranged in the second direction (e.g. y direction).

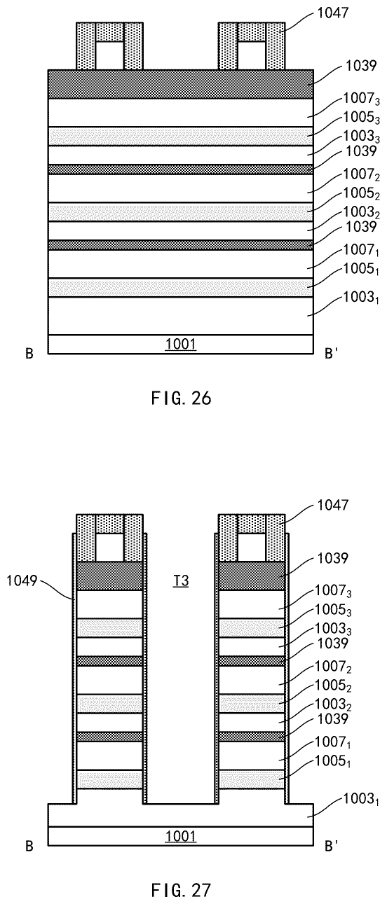

As shown in FIG. 26, anisotropic etching such as RIE in the vertical direction may be performed on the hard mask layer 1043 and the mandrel layer 1041, by using the photoresist 1045 as a mask. Therefore, line patterns of the photoresist 1045 are transferred to the hard mask layer 1043 and the mandrel layer 1041. Afterwards, the photoresist 1045 may be removed. On the sidewalls of the linear hard mask layer 1043 and mandrel layer 1041 extending in the first direction (e.g. x direction), a spacer 1047 may be formed through the spacer formation process. For example, the spacer 1047 may include a nitride whose thickness in the second direction (e.g., y direction) may define the scale of the active region of the selection transistor in the second direction (e.g., y direction). In addition, the width of the mandrel layer 1041 in the second direction (e.g., y direction) may define a spacing between selection transistors adjacent in the second direction (e.g., y direction).

As shown in FIG. 27, anisotropic etching such as RIE in the vertical direction may be performed on the lower isolation layer 1039 and each device layer, by using the hard mask layer 1043 and the spacer 1047 as a mask, so as to form a third processing channel T3 extending in the first direction (e.g., x direction). Etching may stop in the first source/drain layer 1003₁ of the lowermost device layer L1. Therefore, the third processing channel T3 may separate each device layer (except for the first source/drain layer 1003₁ of the lowermost device layer L1) into parts that are separated from each other in the second direction (e.g., y direction). Here, the sidewall of the first source/drain layer 1003₁ may be partially exposed in the third processing channel T3.

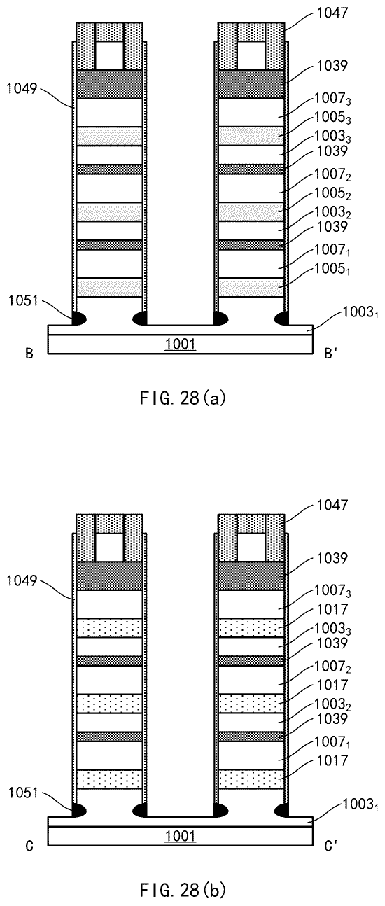

A protective spacer 1049 may be formed on the sidewall of the third processing channel T3 through the spacer formation process. For example, the protective spacer 1049 may include a nitride with a thickness in a range of about 2 nm to 10 nm. To better control a thickness of the protective spacer 1049, atomic layer deposition (ALD) may be used in the spacer formation process. As shown in FIGS. 28(a) and 28(b), in the presence of the protective spacer 1049, the first source/drain layer 1003₁ may be further etched by using the hard mask layer 1043 and the spacer 1047 as the mask. Here, an etching formula with a lateral effect may be used to form an undercut in the first source/drain layer 1003₁. The presence of the protective spacer 1049 may avoid affecting other source/drain layers. The undercut does not extend into the channel defining layer 1005₁ and a well region in the substrate 1001 below to prevent leakage.

In such formed undercut, a metal strip 1051 may be formed by depositing followed by etching back (e.g. RIE in the vertical direction) a metal such as tungsten (W), ruthenium (Ru), molybdenum (Mo), etc. Such metal strip 1051 is embedded in the first source/drain layer 1003₁ at the bottom of each third processing channel T3, and extends in the first direction.

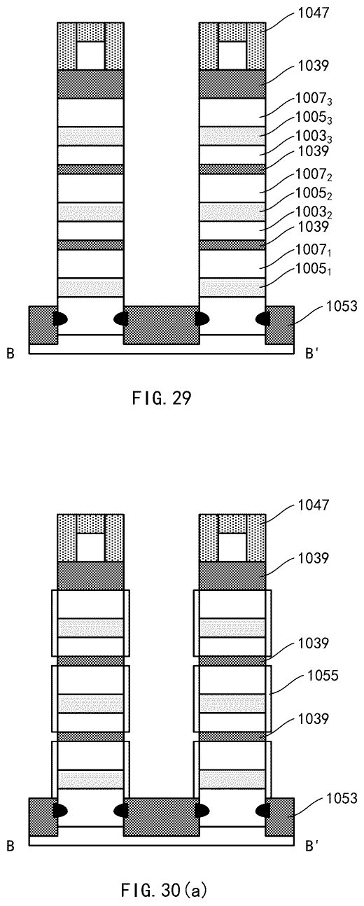

As shown in FIG. 29, the first source/drain layer 1003₁ may be further etched by anisotropic etching such as RIE in the vertical direction, by using the hard mask layer 1043 and the spacer 1047 (as well as the protective spacer 1049) as a mask. The etching may stop in the well region of the substrate 1001. As a result, the third processing channel T3 deepens and further separates the first source/drain layer 1003₁ into parts separated from each other in the second direction (e.g., y direction). Selective etching may be used to etch a certain thickness of nitride to remove the protective spacer 1049, while the hard mask layer 1043 and the spacer 1047 may be retained. In addition, in the third processing channel T3, an isolation layer 1053 may be formed by depositing, planarizing followed by etching back the dielectric material. For example, the isolation layer 1053 may include the same material (in this example, SiC) as the isolation layer 1039. A height of a top surface of the isolation layer 1053 allows the isolation layer 1053 to shield the metal strip 1051 so as to prevent the metal strip 1051 from being damaged in the subsequent step of epitaxial growth of the channel layer, while expose a part of the sidewall of the first source/drain layer 1003₁.

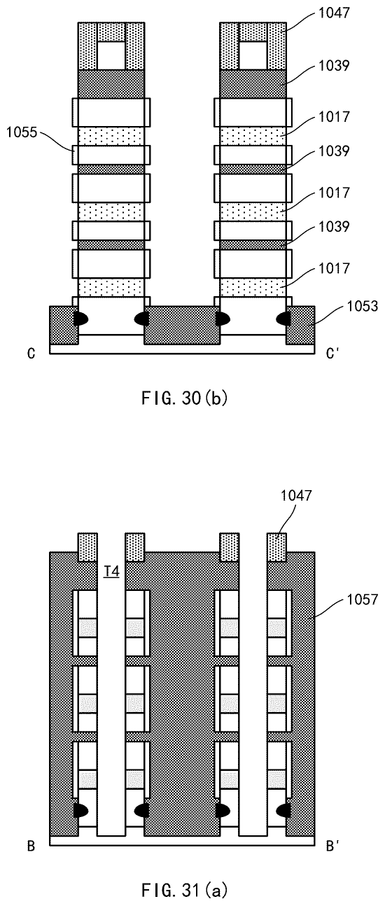

As shown in FIGS. 30(a) and 30(b), a channel layer 1055 may be formed by selective epitaxial growth, for example. For example, the channel layer 1055 may include a semiconductor material, such as Si, that has etching selectivity relative to the channel defining layer with a thickness in a range of about 3 nm to 15 nm. Although the channel layer 1055 is shown as a single layer in the figure, it may be a multi-layer structure.

Due to the selective epitaxial growth, the channel layer 1055 may be self-aligned with the sidewalls of each device layer exposed in the third processing channel T3, and may maintain a substantially identical shape to these exposed sidewalls (please refer to FIG. 33(e), where the shape of the channel layer 1055 is clearly shown). Note that in a case where the sub bit line 1025 includes (doped) polysilicon, the channel layer 1055 may also grow on the sidewall of the sub bit line 1025 exposed in the third processing channel T3.

The channel layer 1055 may be unintentionally doped or lightly doped by in-situ doping during growth, so as to improve the short channel effect, adjust the threshold voltage (Vₜ) of the device, etc. For example, for an n-type selection transistor, p-type doping may be performed with a doping concentration in a range of about 1E17 cm⁻³ to 1E19 cm⁻³. The light doping of the channel layer 1055 may not cause a short circuit between the source/drain layer and the sub bit line, although the channel layers 1055 grown on their respective sidewalls extend continuously to each other as shown in FIG. 33(e).

In addition, annealing may be performed to drive a dopant from the source/drain layer into the corresponding part of the channel layer 1055, so as to reduce external resistance and improve device performance. In FIG. 33(e), an interface between a part (growing on the sidewall of each source/drain layer) of the channel layer 1055 used as a source/drain and a part (growing on the sidewall of the channel defining layer, also known as the “channel portion”) of the channel layer 1055 used as a channel is illustrated by a dashed line. Such interface may be defined by doping concentration. The diffusion of dopant to the part of the channel layer 1055 used as the source/drain may have similar characteristics, so the part of the channel layer 1055 used as the channel may be self-aligned with the corresponding channel defining layer.

In other figures, for the sake of illustration convenience, the difference between the part of the channel layer 1055 used as the source/drain and the part of the channel layer 1055 used as the channel will not be shown.

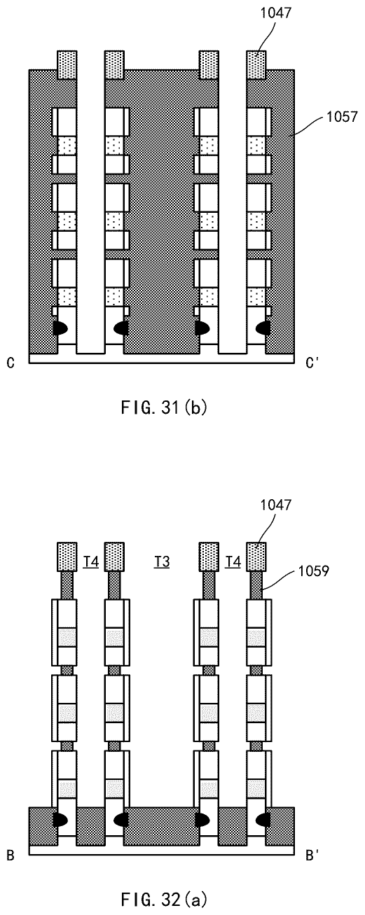

Afterwards, as shown in FIGS. 31(a) and 31(b), the third processing channel T3 may be backfilled by depositing and planarizing the dielectric material, so as to achieve electrical isolation between the device layers on opposite sides of the third processing channel T3. For example, the deposited dielectric material may include the same material (in this example, SiC) as the isolation layer 1053, and is thus integrated as 1057. Here, when planarizing the dielectric material, the mandrel layer 1045 may be used as the stopping position, thus removing the hard mask layer 1047 at the top of the mandrel layer 1045. In addition, the mandrel layer 1045 may be exposed. The mandrel layer 1045 may be removed by selective etching. Therefore, the linear spacer 1047 extending in the first direction is left.

The isolation layer 1057 and the device layers may be sequentially etched through anisotropic etching such as RIE in the vertical direction, by using the spacer 1047 as a mask. Similarly, etching may stop in the well region of the substrate 1001, so as to form a fourth processing channel T4. As involving the etching of the isolation layer 1057, a top surface of the isolation layer 1057 may be lowered relative to the top surface of the spacer 1047.

Therefore, each device layer is divided into parts separated from each other in the second direction by the fourth processing channel T4 and the third processing channel T3 (filled with isolation layers), that is, a plurality of rows extending in the first direction (such as the M rows as described above) arranged in the second direction. Then, each device layer is divided into active regions for selection transistors arranged in the first and second directions. These active regions are arranged in an array (e.g. M rows×N columns). As described above, the first source/drain layer 1003₁ in the lowermost device layer L1 may continuously extend in the first direction and may thus be used as the bit line. The bit line extending in the first direction may be electrically connected to the first source/drain layer (for the lowermost first device layer L1, the bit line itself constitutes the first source/drain layer) in each upper device layer through the sub bit line 1025 extending in the vertical direction. The metal strip 1051 described above may be embedded in the bit line to reduce the resistance of the bit line, but this is not necessary. Alternatively, if the undercut is deeper during the process of forming the undercut as described with reference to FIGS. 28(a) and 28(b) above, the etching of the fourth processing channel T4 may cause the sidewall of the metal strip 1051 formed in the undercut to be directly exposed in the fourth processing channel T4. Therefore, the bit line may include a stack structure of the first source/drain layer 1003₁ and the metal strip 1051, for example, a structure where the lower part of the first source/drain layer 1003₁, the metal strip 1051, and the upper part of the first source/drain layer 1003₁ are sequentially stacked. In this case, the “metal strip” 1051 may also be referred to as the “metal layer” 1051.

Next, the fabrication of the word line may be performed.

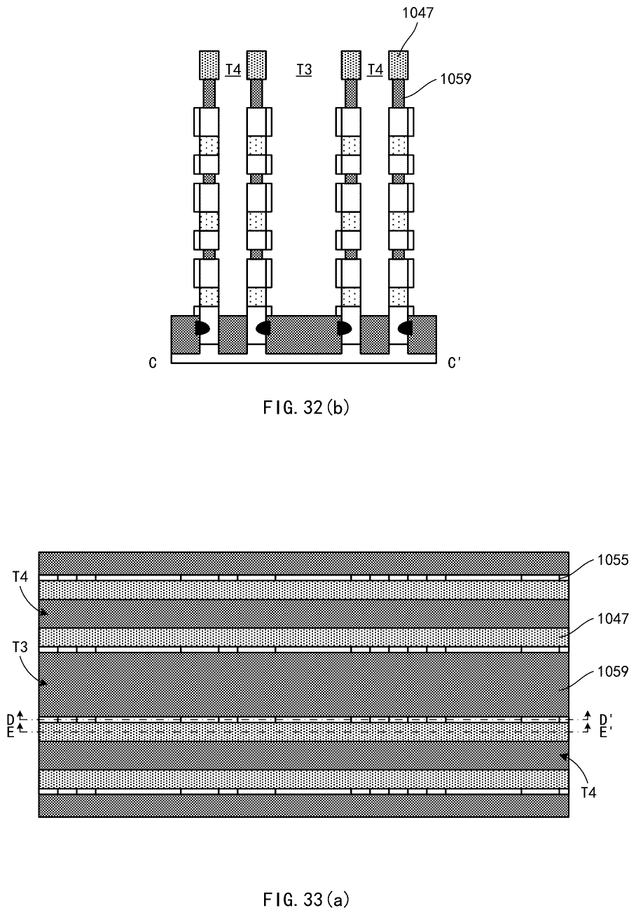

As shown in FIGS. 32(a) and 32(b), the fourth processing channel T4 may be backfilled by depositing and planarizing a dielectric material (such as SiC). Then, the deposited dielectric material and the isolation layer 1057 may be etched back to reopen the third processing channel T3 and the fourth processing channel T4, so as to expose each channel defining layer. In addition, the etching formula used during etching back may have a certain lateral effect, so that the isolation layer 1057 may be relatively recessed in the second direction (for example, the recess extent is at least the thickness of the channel layer 1055, so that the isolation layer 1057 located between the channel layers 1055 in the vertical direction may be removed), so that the sidewall of each gate position retaining layer may be exposed in the third processing channel T3 and the fourth processing channel T4. However, etching back does not completely remove the isolation layer 1057 between the device layers, so as to support the vertical stack structure of the device layers. The etched back dielectric material and the isolation layer 1057 are integrated as 1059.

As shown in FIGS. 33(a) to 33(f), the first gate position retaining layer 1017 and the second gate position retaining layer 1033 may be removed by selective etching. Therefore, a gate accommodating space T5 is released on opposite sides of each channel defining layer (and the channel portion of the channel layer 1055 growing on sidewalls of each channel defining layer) in the first direction. As shown in FIG. 33(d), these gate accommodating spaces T5 are communicated to the third processing channel T3 and the fourth processing channel T4 in the second direction, so as to subsequently form the word line that extends continuously in the second direction by bypassing the channel portion via the gate accommodating space T5.

In addition, the channel defining layers 1005₁, 1005₂, and 1005₃ may be removed by selective etching. Therefore, a gate accommodating space T6 is released between the first source/drain layer and the second source/drain layer in each device layer. As shown in FIG. 33(c), these gate accommodating spaces T6 are communicated to the fourth processing channel T4 on one side. In addition, these gate accommodating spaces T6 are communicated to the third processing channel T3 on the other side via the gate accommodating spaces T5. The gate accommodating spaces T5 communicated to the gate accommodating spaces T6 are schematically shown as dashed lines in FIG. 33(f).

There is a space surrounding the channel portion in each device layer: on one side in the second direction, the space is the gate accommodating space T6 (communicated to the fourth processing channel T4), while on the other side in the second direction, the space is the third processing channel T3 (refer to FIG. 33(c)); on the opposite sides in the first direction, the space is the gate accommodating space T5 (please refer to FIG. 33(e)), where the gate accommodating space T5 is communicated to the third processing channel T3 and the fourth processing channel T4 (refer to FIG. 33(d)). Therefore, the word line surrounding the channel portion in each device layer may be subsequently formed, and thus the GAA configuration is obtained.

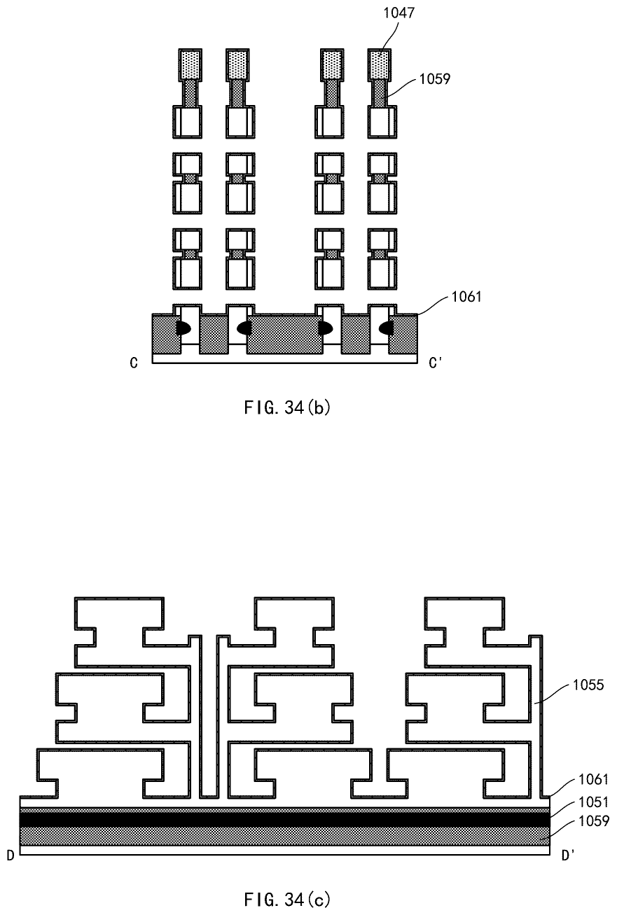

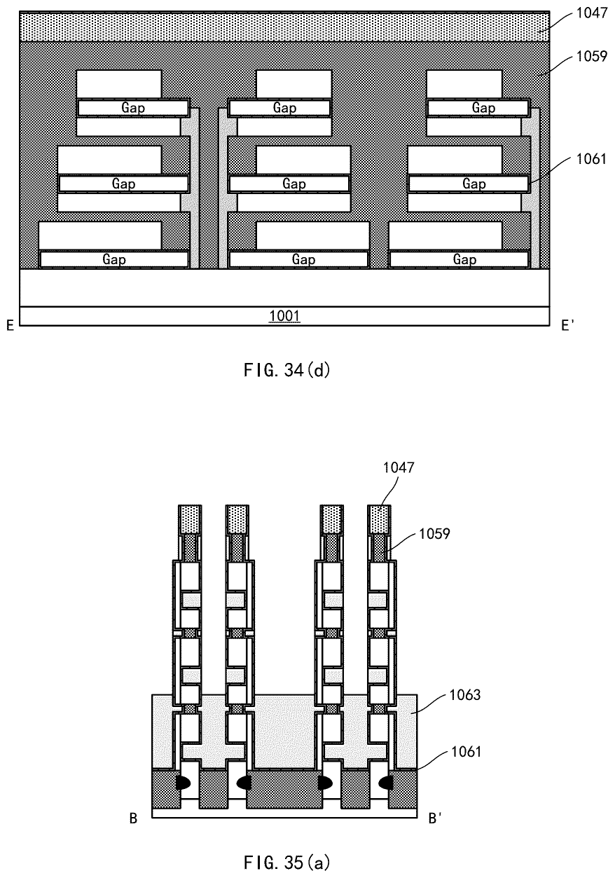

As shown in FIGS. 34(a) to 34(d), a gate dielectric layer 1061 may be formed in a substantially conformal manner by deposition. For example, the gate dielectric layer 1061 may include a high k dielectric such as HfO₂, with a thickness in a range of about 1 nm to 5 nm. Before forming the high k gate dielectric, an oxide interface layer (not shown) with a thickness in a range of about 0.3 nm to 2 nm may also be formed. The surface of the active region (including the first source/drain layer, the second source/drain layer, and the channel layer) may be covered by the gate dielectric layer 1061.

Next, a gate conductor layer corresponding to each device layer (especially the channel portion of the channel layer) may be formed, so as to form the bit line.

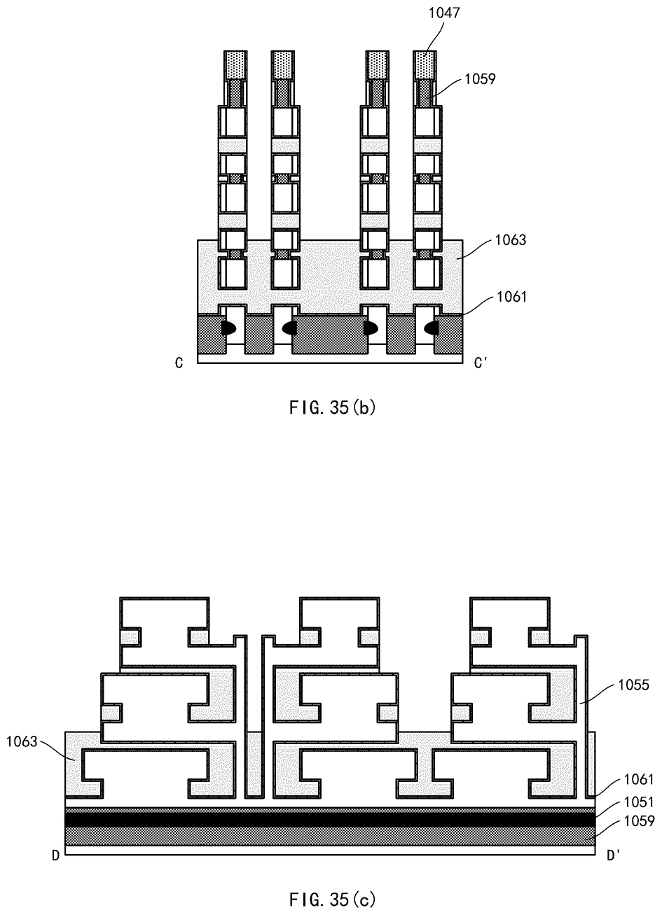

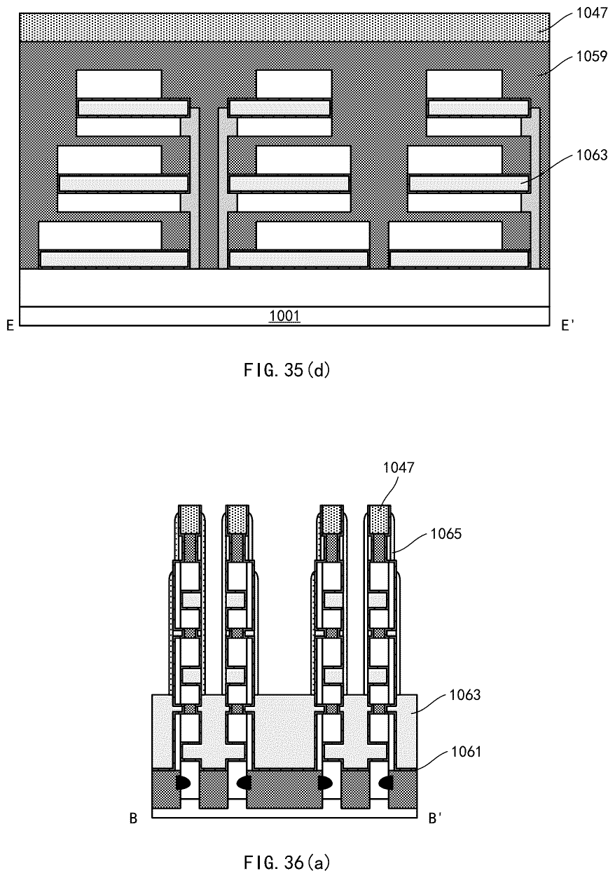

For example, as shown in FIGS. 35(a) to 35(d), a first gate conductor layer 1063 may be formed by deposition, planarization (which may stop at the spacer 1047), followed by etching back (e.g. RIE in the vertical direction). The first gate conductor layer 1063 may include a work function adjustment layer such as a conductive nitride such as TaN, TiN, etc., and a gate conductive material layer such as a metal such as tungsten (W). For example, the work function adjustment layer may be formed in a substantially conformal manner, and the gaps left in the structure may be filled with the gate conductive material layer. Due to etching back, the top surface of the first gate conductor layer 1063 in the third processing channel T3 and the fourth processing channel T4 may be lowered to a height between the top and bottom surfaces of the first source/drain layer 1003₂ in the second device layer L2. In addition, the first gate conductor layer 1063 may also be left in the recess caused by the relative recess of the isolation layer 1059 (in the second direction) relative to adjacent layers, as well as in the gate accommodating spaces T5 and T6.

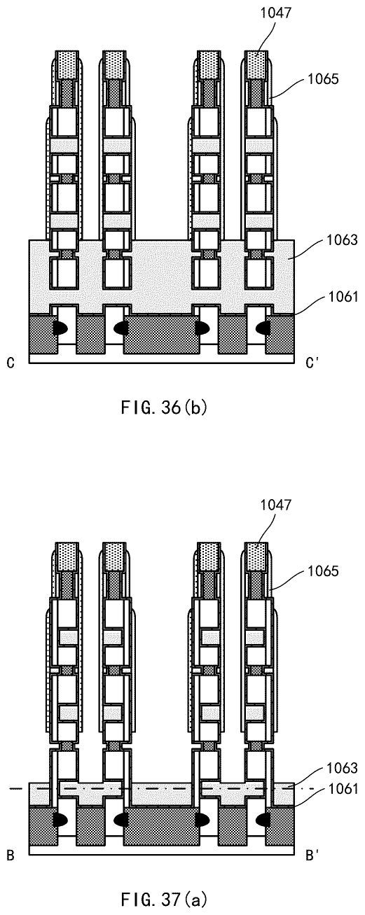

As shown in FIGS. 36(a) and 36(b), a protective spacer 1065 may be formed on the first gate conductor layer 1063 by using the spacer formation process. Considering etching selectivity, the protective spacer 1065 may include, for example, oxide. The protective spacer 1065 may extend vertically on the first gate conductor layer 1063, so as to shield the first gate conductor layer 1063 left in the gate accommodating spaces T5 and T6 (as well as the recess at the end portion of the isolation layer 1059) above the bottom surface of the device layer L2.

As shown in FIGS. 37(a) to 37(c), in the presence of the protective spacer 1065, the first gate conductor layer 1063 may be further etched through isotropic etching. Etching the first gate conductor layer 1063 may lower the top surface of the first gate conductor layer 1063 in the third processing channel T3 and the fourth processing channel T4, for example, lower to close to (for example, slightly lower than) the bottom surface of the second source/drain layer 1007₁ in the device layer L1, so as to reduce the overlap between the first gate conductor layer 1063 and the second source/drain layer 1007₁, thereby reducing parasitic capacitance and improving device reliability. In addition, due to isotropic etching, the first gate conductor layer 1063 remaining in the recess at the end portion of the isolation layer 1059 between device layers L1 and L2 may be removed.

Therefore, as shown in FIG. 37(c), bottoms of the third processing channel T3 and the fourth processing channel T4 as well as the gate accommodating spaces T5 and T6 may be filled with the first gate conductor layer 1063, so that the first gate conductor layer 1063 surrounds the channel portion in the first device layer L1. As clearly shown in FIG. 37(b), the first gate conductor layer 1063 may extend continuously in the second direction.

Afterwards, the protective spacer 1065 may be removed by selective etching.

In the gate accommodating spaces T5 and T6, the first gate conductor layer 1063 is located between the first source/drain layer 1003₁ and the second source/drain layer 1007₁ (or the channel layers 1055 growing on their sidewalls), and may be self-aligned with the channel portion of the first device layer L1. However, in the third processing channel T3, the first gate conductor layer 1063 may not be completely aligned with the channel portion. According to another embodiment, the GAA structure is not formed, but the single side structure is formed. For example, as shown in FIGS. 38(a) and 38(b), a photoresist (not shown) may be formed on the first gate conductor layer 1063, and the photoresist (and the spacer 1047) may be used to remove the first gate conductor layer 1063 from the sidewall of the channel layer 1055 facing the third processing channel T3. Therefore, although the first gate conductor layer 1063 may maintain extending continuously in the second direction (the cross-sectional view along line CC′ may remain substantially the same as the interface diagram shown in FIG. 37(b)), it mainly overlaps with the channel layer 1055 from one side of the channel layer 1055 (facing the gate accommodating space T6). In this case, the part of the first gate conductor layer 1063 close to the channel layer 1055 may be self-aligned with the channel portion.

Hereinafter, the GAA structure is still be used as an example for description, but such description is also applied to the single side structure.

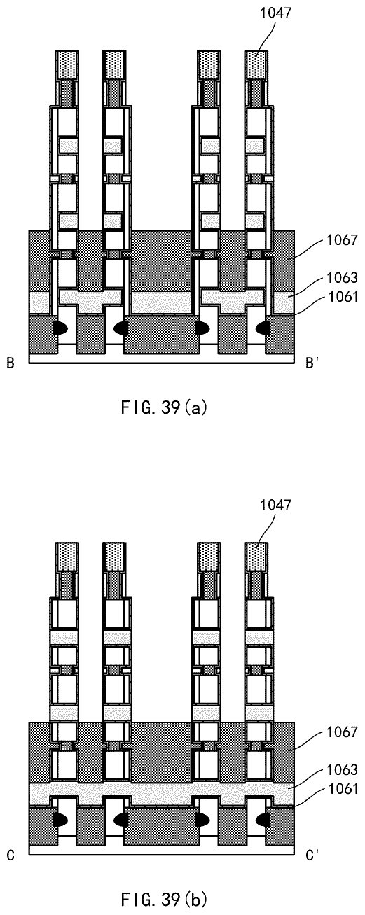

As shown in FIGS. 39(a) and 39(b), an interlayer dielectric layer 1067 may be formed on the first gate conductor layer 1063 by deposition, planarization (which may stop at the spacer 1047), followed by etching back (e.g. RIE in the vertical direction). The interlayer dielectric layer 1067 may include the same material (in this example, SiC) as the isolation layer 1059. A top surface of the interlayer dielectric layer 1067 in the third processing channel T3 and the fourth processing channel T4 may be close to (for example, slightly lower than) the top surface of the first source/drain layer 10032 in the second device layer L2. Due to the formation of the protective spacer 1065 above, the first gate conductor layer 1063 still remains in the gate accommodating spaces T5 and T6 in the second device layer L2 and the third device layer L3, and thus the interlayer dielectric layer 1067 may not enter these gate accommodating spaces.

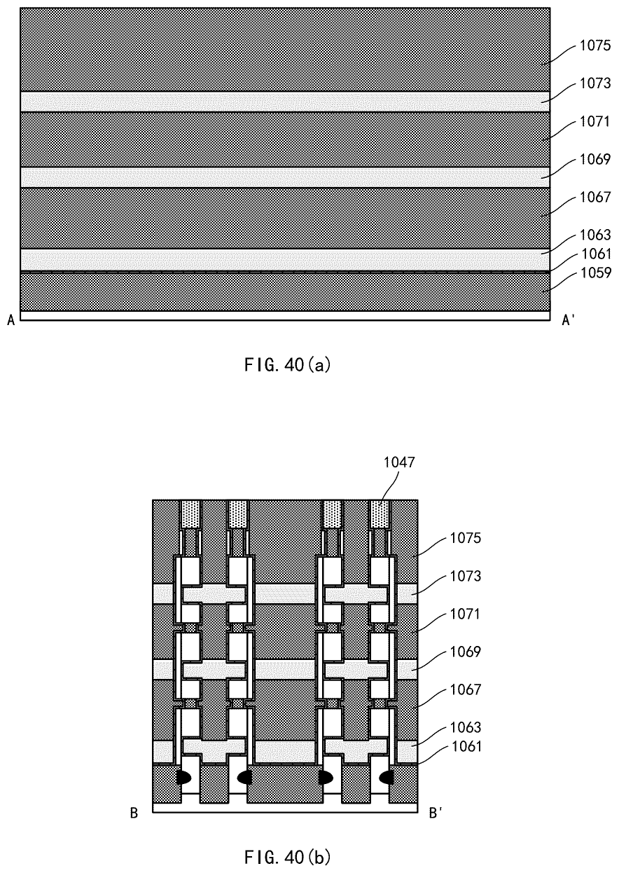

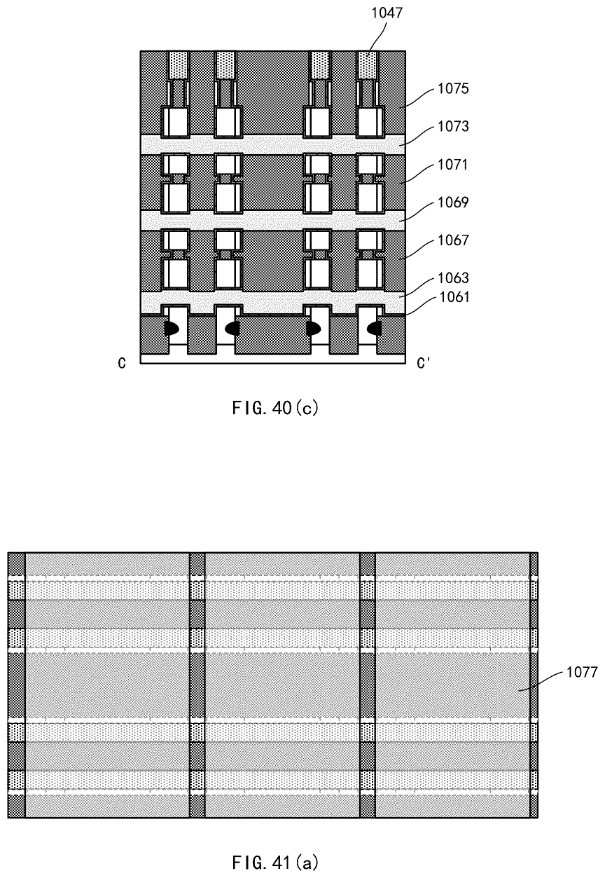

Next, as shown in FIGS. 40(a) to 40(c), a second gate conductor layer 1069 for the second device layer L2 may be similarly formed according to the process described in combination with FIGS. 35(a) to 37(c) as described above, an interlayer dielectric layer 1071 may be formed according to the process described in combination with FIGS. 39(a) and 39(b) as described above, and a third gate conductor layer 1073 and an interlayer dielectric layer 1075 may be similarly formed for the third device layer L3. Here, the top interlayer dielectric layer 1075 may be planarized so that a top surface of the top interlayer dielectric layer 1075 is substantially coplanar with the top surface of the spacer 1047. Each gate conductor layer may have the same material, and each interlayer dielectric layer may have the same material.

As described above, especially as shown in the cross-sectional view in FIG. 37(c), each gate conductor layer may continuously extend on the plane defined in the first and second directions. Each gate conductor layer may be patterned as a word line extending in the second direction (e.g., y direction) (and thus intersect with the bit line extending in the first direction).

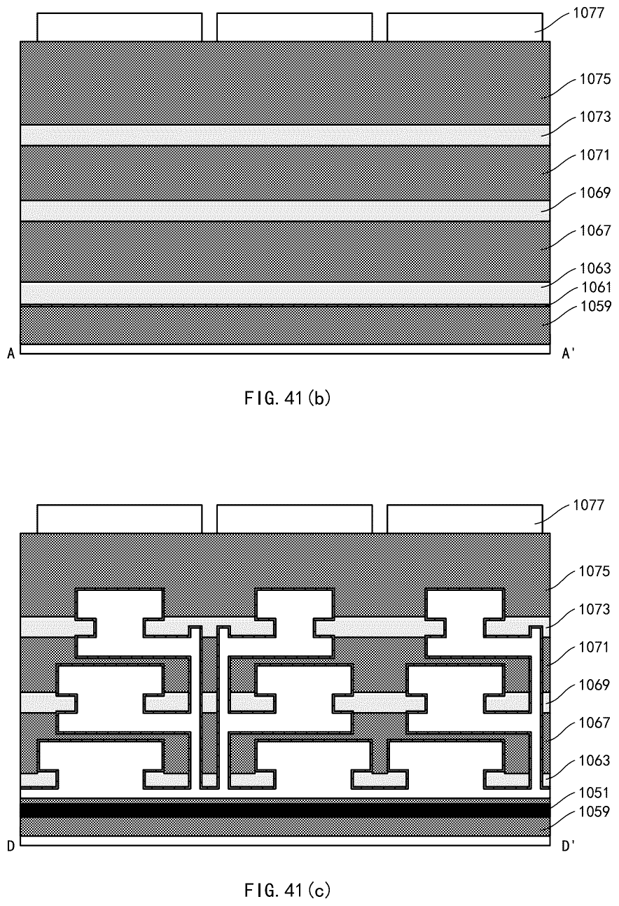

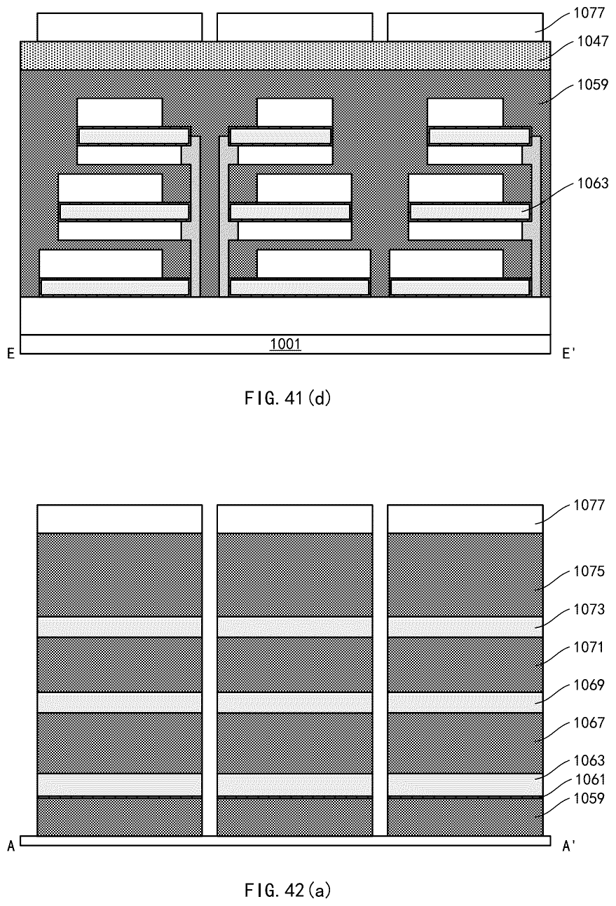

For example, as shown in FIGS. 41(a) to 41(d), a photoresist 1077 may be formed on the interlayer dielectric layer 1075 and patterned by photolithography to cover a series of stripes that extend in the second direction (e.g., y direction), where these stripes will then define the word lines. In the first direction, these stripes may cover the corresponding channel portion in each lower device layer (between the first processing channel T1 and the second processing channel T2 adjacent to each other) and at least part of the fifth processing channel T5 on opposite sides of the channel portion.

As shown in FIGS. 42(a) to 42(c), the photoresist 1077 may be used as a mask to etch downwards the interlayer dielectric layers 1075, 1071 and 1067, the isolation layer 1059, as well as the gate conductor layers 1073, 1069 and 1063 (e.g. through RIE in the vertical direction). Etching may stop at the Si material below (e.g. the substrate 1001, the first source/drain layer 1003₁ of the lowermost first device layer L1, and the channel layer 1055 growing on the sidewall of the first source/drain layer 1003₁ of the lowermost first device layer L1). Therefore, each gate conductor layer 1063, 1069 or 1073 may be patterned as a strip extending in the second direction (e.g., y direction) as defined by the photoresist 1077, serving as a word line (WL). The cross-sectional view of FIG. 42(c) clearly illustrates the word line extending in the second direction (e.g., y direction) in the first device layer L1. Afterwards, the photoresist 1077 may be removed.

The cross-sectional view in FIG. 42(d) illustrates the word line in the case of a single side device. Similarly, the word line may extend in the second direction (e.g., y direction) and may cover (only) one side of the channel portion, without covering other sides of the channel portion.

During etching, the selected etching formula may have selectivity relative to the spacer 1047, so that the spacer 1047 may be substantially unaffected (please refer to FIG. 41(d), at the EE′ section shown in the figure, the structure remains substantially the same after etching). According to another embodiment, as shown in FIG. 43, the spacer 1047 may also be etched. In the following, the description will still take the example where the spacer 1047 is not etched, but these descriptions are also applied to the case where the spacer 1047 is etched.

According to another embodiment, instead of using a common mask to pattern all gate conductor layers, when combining the processes described with reference to FIGS. 35(a) to 37(c) above to form the gate conductor layer for each device layer, the formed gate conductor layer may be directly patterned as a stripe extending in the second direction, then the interlayer dielectric layer is formed similarly, and a gate conductor layer of the upper device layer is formed on the interlayer dielectric layer and patterned as a strip extending in the second direction. That is, the gate conductor layer may be formed layer by layer and patterned as the word line.

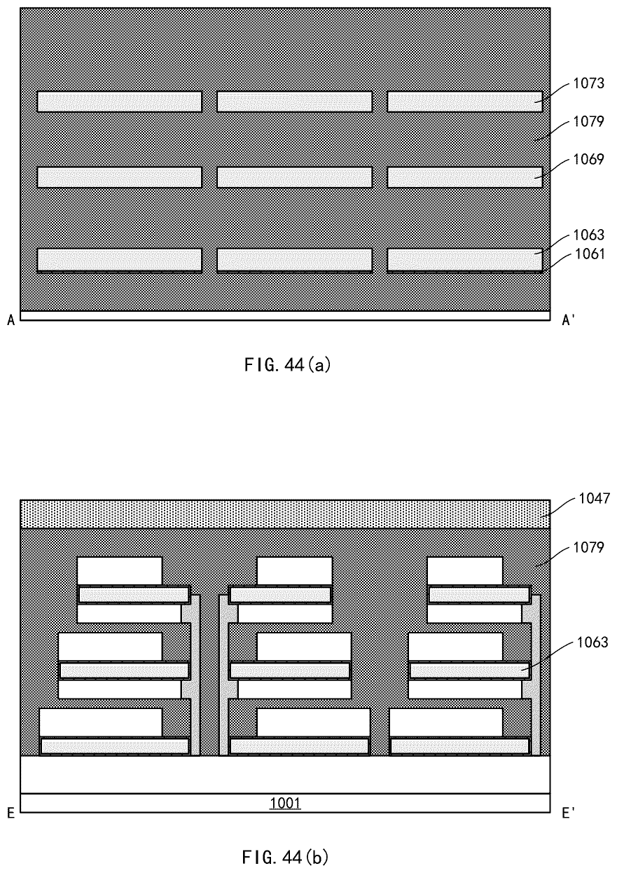

As shown in FIGS. 44(a) and 44(b), the gap formed by patterning the word line may be filled with a dielectric material by depositing and planarizing a dielectric (which may stop at the spacer 1047), so as to achieve electrical isolation. The filled dielectric may include the same material as the previously formed isolation layer and interlayer dielectric layer, such as SiC, and is thus integrated as 1079.

In this way, the 3D array of selection transistors is obtained. Such array, for example, is described in conjunction with FIGS. 1(a) and 1(b) above, except that FIGS. 1(a) and 1(b) mainly show structures of the active region of the selection transistor, the word line, and the bit line, but do not show other components such as the isolation layer and the interlayer dielectric layer.

An array of memory elements electrically connected to the 3D array of the selection transistors may be fabricated.

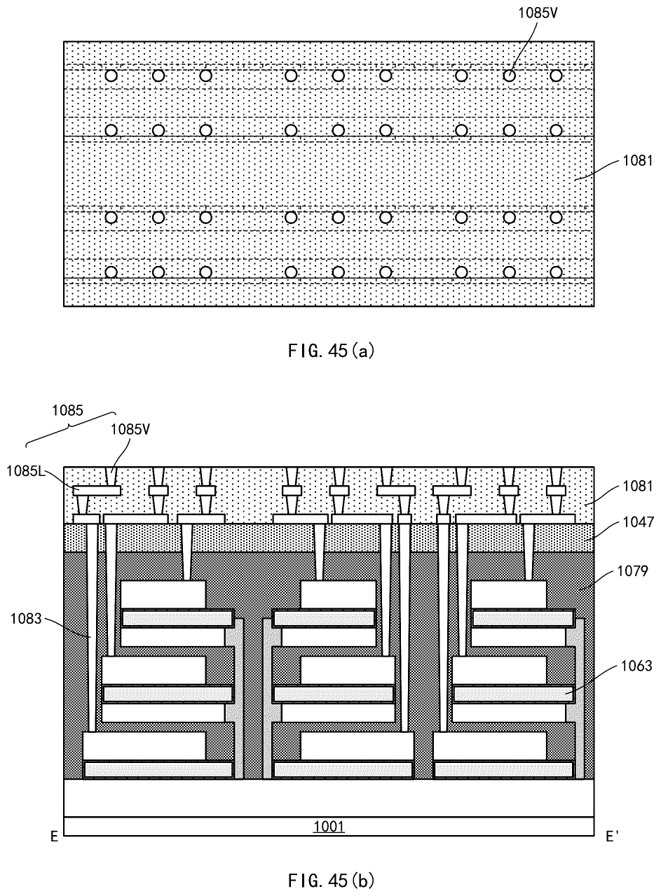

For example, as shown in FIGS. 45(a) and 45(b), a contact portion 1083 to each selection transistor (especially its upper source/drain region) may be formed in the interlayer dielectric layer 1079. For example, the interlayer dielectric layer 1079 may be etched to form a hole, and the hole is filled with a metal such as W, Ru, Co, etc. to form the contact portion 1083. Due to the step structure described above, respective contact portions 1083 of selection transistors in different layers may not interfere with each other.

In addition, a redistribution layer may be formed on the 3D array of the selection transistors. The redistribution layer may include an interlayer dielectric layer 1081 (e.g. oxide) and a redistribution structure 1085 provided in the interlayer dielectric layer 1081. The redistribution structure 1085 may include a redistribution wiring 1085L and a redistribution via hole 1085V. The redistribution wiring 1085L may extend within a plane substantially parallel to the surface of the substrate, for example, to achieve wiring routing. The redistribution via hole 1085V may achieve an electrical connection between redistribution wirings 1085L of different layers. According to the design, one or more layers of redistribution wirings 1085L and/or one or more layers of redistribution via holes 1085V may be formed. The redistribution wiring 1085L and the redistribution via hole 1085V may include a conductive material such as copper (Cu).

FIG. 45(a) shows a layout of top redistribution via holes 1085V in the redistribution structure. Although the redistribution via holes 1085V are shown as arranged substantially along the spacer 1047, the present disclosure is not limited to this. For example, the redistribution via holes 1085V may be provided substantially evenly within the plane. By designing different redistribution structures, different layouts of redistribution via holes 1085V may be achieved to optimize an area occupied by the device and device performance. In particular, the 3D array of selection transistors may be optimized (for example, less or even not affected by the layout of memory elements) to save area and increase the effective width or conduction current of the device.

As shown in FIGS. 46(a) and 46(b), a memory element may be formed in the interlayer dielectric layer 1081. For example, as shown in FIG. 46(a), the memory element 1087 may include a capacitor with a lower electrode 1087L, an upper electrode 1087U, and an intermediate dielectric layer 1087I between the lower electrode 1087L and the upper electrode 1087U. The lower electrode 1087L and the upper electrode 1087U may include a metal film, and the intermediate dielectric layer 1087I may include a high k dielectric. Alternatively, as shown in FIG. 46(b), the memory element 1089 may include an MTJ with a fixed layer 1089L, a tunnel barrier layer 1089I, and a free layer 1089U. For example, the fixed layer 1089L may include CoFeB, with a metal film (such as Ta, Ru, or Cr) provided on a lower surface of the fixed layer 1089L to be in contact with the redistribution via hole 1085V; the free layer 1089U may include CoFeB, with a metal film (such as Ta, Ru, or Cr) provided on an upper surface of the free layer 1089U to be in contact with the subsequently formed contact portion; and the tunnel barrier layer 1089I may include MgO, for example, with a thickness in a range of about 0.3 nm to 3 nm. In the plan view, each MTJ may have a diameter in a range of about 10 nm to 100 nm.

Each memory element may be electrically connected to the redistribution via hole 1085V of the top layer in the redistribution structure on one side (the lower side in the figure), and to the corresponding contact portion on the other side (the upper side in the figure), where the contact portion may be grounded, for example.

In addition, an interlayer dielectric layer may be further formed to cover the memory element and corresponding contact portion. Such interlayer dielectric layer is integrated with the previous interlayer dielectric layer as 1081′.

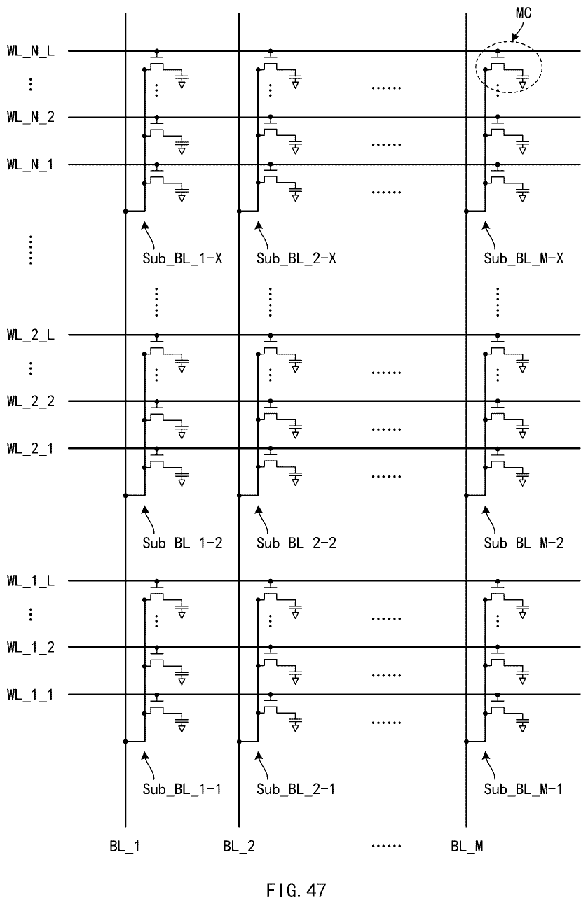

FIG. 47 schematically shows an equivalent circuit diagram of a memory device according to an embodiment of the present disclosure.

As shown in FIG. 47, the memory device according to embodiments includes an array of memory cells MC. Each MC may include a selection transistor and a memory element. One end of the memory element may be connected to a corresponding selection transistor, so that the memory element may be connected to a corresponding bit line through the selection transistor for receiving data from the bit line (for example, in a write operation) or sending stored data to the bit line (for example, in a read operation). The other end of the memory element may be grounded, for example. The gate electrode of the selection transistor may be electrically connected to the corresponding word line. The selection transistor may be addressed through word lines and bit lines.

As described above, the selection transistors may be arranged as a 3D array, such as a 3D array of M×N×L. In each layer from the first layer to the L^{th} layer, the selection transistors may be arranged in an array of M rows×N columns. Correspondingly, M bit lines BL_1, BL_2, . . . , BL_M may be provided. The selection transistors of the corresponding row (e.g., the i^{th} row) in each layer may be electrically connected to the corresponding bit line BL_i through the sub bit lines Sub_BL_i-1, Sub_BL_i-2, . . . , Sub_BL_i-N. Corresponding to each layer from the first layer to the L^{th} layer, L word line layers may be provided, and each word line layer (such as the k^{th} layer) may include N word lines WL_1-k, WL_2-k, . . . , WL-N-k. Each word line may surround at least part of the periphery of the channel portion of the selection transistor of the corresponding column in the corresponding layer.

Therefore, each selection transistor TR_i-j-k may be electrically connected to the corresponding bit line BL_i through the sub bit line Sub_BL_i-j. The gate electrode of each selection transistor is defined by the corresponding word line WL_j-k, and thus electrically connected to a place between the word line WL_j-k and the bit line BL_i.

The memory device according to embodiments of the present disclosure has an improved integration density and may be applied to various electronic apparatuses. For example, the memory device may store various programs, applications and data required for an operation of the electronic apparatus. The electronic apparatus may further include a processor cooperated with the memory device. For example, the processor may operate the electronic apparatus by running a program stored in the memory device. Such electronic apparatus includes, for example, a smart phone, a personal computer (PC), a tablet, an artificial intelligence apparatus, a wearable apparatus, a mobile power supply, an automotive electronic apparatus, a communication apparatus, or an Internet of Things (IoT) apparatus, etc.

In the above description, the technical details such as patterning and etching of each layer are not described in detail. However, those skilled in the art should understand that various technical means may be employed to form a layer, a region or the like of having a desired shape. In addition, in order to form the same structure, those skilled in the art may also design a method that is not completely the same as the method described above. In addition, although the respective embodiments are described above separately, this does not mean that the measures in the respective embodiments cannot be advantageously used in combination.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should fall within the scope of the present disclosure.

What is claimed is:

1. A memory device, comprising:
a plurality of device layers stacked on a substrate in a vertical direction relative to the substrate, wherein each of the plurality of device layers comprises an array of active regions of selection transistors, the active regions in the array are arranged in rows in a first direction and in columns in a second direction, and the active region comprises a lower source/drain region and an upper source/drain region at different heights relative to the substrate, as well as a channel portion located between the lower source/drain region and the upper source/drain region;
a plurality of bit lines arranged in the second direction, wherein each of the plurality of bit lines extends in the first direction along a corresponding row in the array;
a plurality of word line layers stacked in the vertical direction and corresponding to the plurality of device layers, respectively, wherein each of the plurality of word line layers comprises a plurality of word lines arranged in the first direction, and each of the plurality of word lines extends in the second direction to at least partially surround a channel portion of an active region in a corresponding column of the device layer corresponding to the word line layer;
a plurality of sub bit lines extending vertically from each of the plurality of bit lines, wherein each of the plurality of sub bit lines is electrically connected to a lower source/drain region of an active region in a corresponding row of the bit line in each device layer above the bit line; and
a memory element electrically connected to the upper source/drain region of each active region.

2. The memory device according to claim 1, wherein each of the plurality of bit lines is self-aligned with the corresponding row in the array.

3. The memory device according to claim 1, wherein the plurality of bit lines constitute lower source/drain regions of active regions in a lowermost device layer among the plurality of device layers.

4. The memory device according to claim 1, wherein each of the plurality of bit lines further comprises:
a metal strip embedded into the bit line from a side of the bit line in the second direction and extending in the first direction.

5. The memory device according to claim 4, wherein metal strips in every two adjacent bit lines among the plurality of bit lines are embedded into respective bit lines from sides of the two adjacent bit lines away from each other.

6. The memory device according to claim 1, wherein each of the plurality of bit lines further comprises: a metal layer extending in the first direction.

7. The memory device according to claim 1, wherein the word line extends in the second direction to surround the channel portion of the active region.

8. The memory device according to claim 1, wherein the word line extends in the second direction to partially surround the channel portion of the active region.

9. The memory device according to claim 8, wherein for each channel portion in a corresponding column of a corresponding device layer, the word line extends between the channel portion and one of two adjacent channel portions adjacent to the channel portion in the second direction, and does not extend between the channel portion and the other of the two adjacent channel portions, and the word line bypasses the channel portion from both sides of the channel portion in the first direction to extend continuously in the second direction.

10. The memory device according to claim 1, wherein the sub bit line is self-aligned with a corresponding bit line.

11. The memory device according to claim 1, wherein a pair of sub bit lines on each bit line are provided every pair of adjacent active regions, and respective sub bit lines of the plurality of bit lines are arranged in a column in the second direction.

12. The memory device according to claim 11, wherein the sub bit line comprises:
a vertical extension portion extending vertically from a corresponding bit line; and
a lateral extension portion extending laterally from the vertical extension portion towards the lower source/drain region,
wherein respective lateral extension portions of the pair of sub bit lines extend in opposite directions.

13. The memory device according to claim 12, wherein the lateral extension portion is self-aligned with the lower source/drain region.

14. The memory device according to claim 1, wherein the active region comprises:
a lower source/drain layer, wherein the lower source/drain region comprises the lower source/drain layer;
an upper source/drain layer, wherein the upper source/drain region comprises the upper source/drain layer; and
a channel layer comprising a part extending between the lower source/drain layer and the upper source/drain layer, wherein the part defines the channel portion,
wherein opposite end portions of the part of the channel layer extending between the lower source/drain layer and the upper source/drain layer in the first direction are recessed in the first direction relative to corresponding end portions of the lower source/drain layer and corresponding end portions of the upper source/drain layer, so that the word line passes through a space defined by the lower source/drain layer and the upper source/drain layer at the opposite end portions of the part of the channel layer extending between the lower source/drain layer and the upper source/drain layer in the first direction, so as to extend in the second direction.

15. The memory device according to claim 14, wherein the channel layer is an epitaxial layer formed on a sidewall of the lower source/drain layer as well as a sidewall of the upper source/drain layer in the second direction.

16. The memory device according to claim 15, wherein channel layers of each pair of adjacent active regions in each column are provided on sidewalls of respective lower source/drain layers of the pair of adjacent active regions away from each other and sidewalls of respective upper source/drain layers of the pair of adjacent active regions away from each other.

17. The memory device according to claim 15, wherein the sub bit line comprises doped polycrystalline silicon, and the epitaxial layer further extends to a sidewall of the sub bit line.

18. The memory device according to claim 14, wherein an end portion of a lower source/drain layer and an end portion of an upper source/drain layer of an active region in a lower device layer on a side opposite to a sub bit line connected to the active region in the lower device layer protrude relative to a corresponding end portion of a lower source/drain layer and a corresponding end portion of an upper source/drain layer of an active region in an upper device layer, and
wherein the memory device further comprises:
a contact portion landed on a protruding end portion of the upper source/drain layer, wherein the memory element is electrically connected to the upper source/drain layer through the contact portion.

19. The memory device according to claim 18, further comprising:
a redistribution layer comprising a redistribution line and a redistribution via hole,
wherein the memory element is electrically connected to the contact portion through the redistribution layer.

20. The memory device according to claim 18, further comprising:
a metal silicide layer on the end portion of the lower source/drain layer of the active region, wherein the metal silicide layer extends on a sidewall and an upper surface of the lower source/drain layer at the end portion of the lower source/drain layer; and
a metal silicide layer on the end portion of the upper source/drain layer of the active region, wherein the metal silicide layer extends on a sidewall and a lower surface of the upper source/drain layer at the end portion of the upper source/drain layer.

21. The memory device according to claim 14, wherein an end portion of the lower source/drain layer of each active region on a side of a sub bit line connected to the active region protrudes relative to an end portion of the upper source/drain layer of the active region.

22. The memory device according to claim 21, wherein end portions of the lower source/drain layers of the active regions in different device layers on the side of the sub bit line are substantially aligned in the vertical direction, and end portions of the upper source/drain layers of the active regions in different device layers on the side of the sub bit line are substantially aligned in the vertical direction.

23. The memory device according to claim 1, further comprising:
an isolation layer between different device layers, wherein the isolation layer comprises a dielectric interface or boundary.

24. The memory device according to claim 1, wherein the memory element comprises a capacitor or a magnetic tunnel junction.

25. A method of manufacturing a memory device, comprising:
providing a plurality of device layers on a substrate, wherein each of the plurality of device layers comprises a first source/drain layer, a channel defining layer, and a second source/drain layer sequentially stacked in a vertical direction relative to the substrate, and an isolation defining layer is provided between device layers;
forming, in the plurality of device layers, a plurality of first processing channels extending vertically, wherein the plurality of first processing channels are arranged in a first direction and extend in a second direction intersecting with the first direction, and a bottom portion of each of the plurality of first processing channels is defined by a first source/drain layer in a lowermost device layer among the plurality of device layers;
recessing in the first direction, via the first processing channel, an end portion of the channel defining layer in each device layer in the first direction relative to a corresponding end portion of the first source/drain layer and a corresponding end portion of the second source/drain layer, and forming a first gate position retaining layer in a resulting recess;
replacing, via the first processing channel, a part of the isolation defining layer facing the first processing channel with an isolation layer;
recessing in the first direction, via the first processing channel, the second source/drain layer in each device layer exposed in the first processing channel relative to the first source/drain layer in the device layer exposed in the first processing channel;
forming, on the first source/drain layer in the lowermost device layer exposed at the bottom portion of the first processing channel, a sub bit line along a sidewall of the first processing channel, wherein the sub bit line is in contact with the first source/drain layer in each device layer exposed in the first processing channel;
forming, in the plurality of device layers, a plurality of second processing channels extending vertically, wherein the plurality of second processing channels are arranged alternately with the first processing channels in the first direction and extend in the second direction, and the plurality of device layers form a step structure at the second processing channel;
recessing in the first direction, via the second processing channel, the end portion of the channel defining layer in each device layer in the first direction relative to the corresponding end portion of the first source/drain layer and the corresponding end portion of the second source/drain layer, and forming a second gate position retaining layer in a resulting recess;
replacing, via the second processing channel, a remaining part of the isolation defining layer facing the second processing channel with an isolation layer;
forming a plurality of third processing channels that pass through the plurality of device layers, wherein the plurality of third processing channels are arranged in the second direction and extend in the first direction;
growing, by selective epitaxial growth, a channel layer on a sidewall of each device layer exposed in the third processing channel;
forming a plurality of fourth processing channels that pass through the plurality of device layers, wherein the plurality of fourth processing channels are arranged alternately with the third processing channels in the second direction and extend in the first direction;
removing, via the fourth processing channel, the channel defining layer, the first gate position retaining layer, and the second gate position retaining layer; and
forming, on the substrate, a word line layer corresponding to each device layer, wherein each word line layer comprises a plurality of word lines, the word line extends in the second direction to at least partially surround a part of the channel layer between the first source/drain layer and the second source/drain layer.

26. The method according to claim 25, wherein the plurality of device layers and the isolation defining layer are provided by epitaxial growth.

27. The method according to claim 25, wherein the word line passes through a space retained by the first gate position retaining layer and the second gate position retaining layer, so as to bypass the part of the channel layer between the first source/drain layer and the second source/drain layer to extend continuously in the second direction.

28. The method according to claim 25, wherein the sub bit line is formed through a spacer formation process.

29. The method according to claim 25, wherein an interface or a boundary exists between the isolation layer replaced via the first processing channel and the isolation layer replaced via the second processing channel.

30. The method according to claim 25, wherein forming the plurality of third processing channels comprises:
forming a plurality of mandrel layers extending in the first direction;
forming, on a sidewall of each of the plurality of mandrel layers, a spacer extending in the first direction; and
selectively etching the plurality of device layers by using the plurality of mandrel layers and spacers on respective sidewalls of the plurality of mandrel layers as an etching mask, and
wherein forming the plurality of fourth processing channels comprises:
removing the plurality of mandrel layers; and
selectively etching the plurality of device layers by using the spacers on respective sidewalls of the plurality of mandrel layers as an etching mask.

31. The method according to claim 25, wherein replacing, via the second processing channel, the remaining part of the isolation defining layer with the isolation layer comprises: removing, via the second processing channel, the remaining part of the isolation defining layer, and
wherein the method further comprises: performing a silicification processing on a part of a surface of the device layer exposed by the second processing channel and exposed by a removal of the remaining part of the isolation defining layer.

32. The method according to claim 25, further comprising:
patterning the word line, so that the word line covers a surface of the channel layer on a side facing the channel defining layer, and does not cover a surface of the channel layer on a side away from the channel defining layer.

33. An electronic apparatus, comprising the memory device according to claim 1.

34. The electronic apparatus according to claim 33, wherein the electronic apparatus comprises: a smart phone, a computer, a tablet computer, an artificial intelligence apparatus, a wearable apparatus, a mobile power supply, an automotive electronic apparatus, a communication apparatus, or an Internet of things apparatus.
